(19) United States
(12) Patent Application Publication
(10) Pub. No.: US 2026/0181878 A1
(43) Pub. Date: Jun. 25, 2026

(54) SEMICONDUCTOR MEMORY DEVICE

(71) Applicant: Samsung Electronics Co., Ltd., Suwon-si (KR)

(72) Inventors: Sanghyun Sung, Suwon-si (KR); Jinwoo Han, Suwon-si (KR)

(21) Appl. No.: 19/312,919

(22) Filed: Aug. 28, 2025

(30) Foreign Application Priority Data
Dec. 19, 2024 (KR) 10-2024-0191705

(51) Int. Cl. H10B 12/00; H01L 23/00; H10B 20/25; H10D 80/30

(52) U.S. Cl. CPC H10B 12/50; H10B 12/315; H10B 12/482; H10B 12/488; H10B 20/25; H10D 80/30; H10W 90/792

(57) ABSTRACT

A semiconductor memory device includes a first stack structure including a first substrate, a memory cell region including a plurality of memory cells and a plurality of cell capacitors arranged three-dimensionally on the first substrate, and an antifuse cell region including a plurality of antifuse cells and a plurality of antifuse capacitors arranged three-dimensionally on the first substrate and a second stack structure disposed on the first stack structure and including a second substrate, a core region positioned to vertically overlap the memory cell region on the second substrate and electrically connected to the memory cell region and a peripheral circuit region positioned to vertically overlap the antifuse cell region on the second substrate.

### CROSS-REFERENCE TO RELATED APPLICATION

This application and claims priority under 35 USC § 119 to Korean Patent Application No. 10-2024-0191705, filed on Dec. 19, 2024, in the Korean Intellectual Property Office, the disclosures of which is incorporated by reference herein in its entirety.

### BACKGROUND

The disclosures relates to a semiconductor memory device, and more particularly, to a three-dimensional (3D) semiconductor memory device.

As miniaturization, multi-functionality, and high performance of electronic products have been demanded, high-capacity semiconductor memory devices have been required, and to provide high-capacity semiconductor memory devices, increased integration has been required. 3D semiconductor memory devices having increased memory capacity by stacking a plurality of memory cells vertically on a substrate have been proposed.

When a defect occurs in some of the memory cells, a method of replacing the defective memory cells using redundancy cells manufactured in advance within the memory device is used. Repair operations using redundancy cells are mainly performed using antifuse elements, and the antifuse elements have high resistance when not programmed and low resistance after a program operation. Antifuse elements occupy a relatively large area within a peripheral circuit region.

### SUMMARY

The disclosure provides a three-dimensional (3D) semiconductor memory device capable of improving the space efficiency of a chip by changing the arrangement of a peripheral circuit including an antifuse element.

However, the problems to be addressed by the disclosure are not limited to the problems mentioned above, and other problems may be clearly understood by those skilled in the art from the description below.

According to an aspect of the disclosures, there is provided a semiconductor memory device including a first stack structure including a first substrate, a memory cell region including a plurality of memory cells and a plurality of cell capacitors arranged three-dimensionally on the first substrate and an antifuse cell region including a plurality of antifuse cells and a plurality of antifuse capacitors arranged three-dimensionally on the first substrate and a second stack structure disposed on the first stack structure and including a second substrate, a core region positioned to vertically overlap the memory cell region on the second substrate and electrically connected to the memory cell region and a peripheral circuit region positioned to vertically overlap the antifuse cell region on the second substrate.

According to another aspect of the disclosures, there is provided a semiconductor memory device including a first stack structure including a first substrate, a memory cell region including a plurality of memory cells and a plurality of cell capacitors arranged three-dimensionally on the first substrate and an antifuse cell region including a plurality of antifuse cells and a plurality of antifuse capacitors arranged three-dimensionally on the first substrate and a second stack structure disposed on the first stack structure and including a second substrate, a core region positioned to vertically overlap the memory cell region on the second substrate and electrically connected to the memory cell region and a peripheral circuit region positioned to vertically overlap the antifuse cell region on the second substrate, wherein each of the plurality of antifuse cells includes a second semiconductor pattern extending in a first horizontal direction parallel to an upper surface of the first substrate in the antifuse cell region, the second semiconductor pattern including a first antifuse impurity region and a second antifuse impurity region arranged in the first horizontal direction with an antifuse channel region therebetween, a second word line surrounding the antifuse channel region of the second semiconductor pattern and extending in a second horizontal direction intersecting the first horizontal direction, and a second bit line contacting the first antifuse impurity region of the second semiconductor pattern and extending in a vertical direction wherein an antifuse capacitor of the plurality of antifuse capacitors is in contact with the second antifuse impurity region of the second semiconductor pattern.

According to another aspect of the disclosures, there is provided a semiconductor memory device including a first stack structure including a first substrate, a memory cell region including a plurality of memory cells and a plurality of cell capacitors arranged three-dimensionally on the first substrate, and an antifuse cell region including a plurality of antifuse cells and a plurality of antifuse capacitors arranged three-dimensionally on the first substrate and a second stack structure disposed on the first stack structure and including a second substrate, a core region positioned to vertically overlap the memory cell region on the second substrate and electrically connected to the memory cell region and a peripheral circuit region positioned to vertically overlap the antifuse cell region on the second substrate, wherein each of the plurality of memory cells of the first stack structure includes a first semiconductor pattern on the first substrate in the memory cell region and extending in a first horizontal direction parallel to an upper surface of the first substrate, a word line surrounding the first semiconductor pattern and extending in a second horizontal direction parallel to an upper surface of the first substrate, and a first bit line connected to a first end portion of the first semiconductor pattern and extending in a vertical direction, wherein each of the plurality of antifuse cells of the first stack structure includes a second semiconductor pattern on the first substrate in the antifuse cell region and extending in the first horizontal direction, a word line surrounding the second semiconductor pattern and extending in the second horizontal direction, and a second bit line connected to a first end portion of the second semiconductor pattern and extending in the vertical direction of the first substrate, and wherein the first semiconductor pattern, the second semiconductor pattern, a cell capacitor of the plurality of cell capacitors, and the antifuse capacitor are arranged at the same vertical level.

### BRIEF DESCRIPTION OF THE DRAWINGS

Embodiments will be more clearly understood from the following detailed description taken in conjunction with the accompanying drawings in which:

FIG. 1 is a block diagram schematically illustrating a semiconductor memory device according to embodiments;

FIG. 2 is a circuit diagram illustrating a memory cell array illustrated in FIG. 1;

FIG. 3 is a circuit diagram illustrating an antifuse cell array illustrated in FIG. 1;

FIG. 4 is a perspective view illustrating a semiconductor memory device according to embodiments;

FIG. 5 is a schematic perspective view illustrating a memory cell region of a first stack structure of FIG. 4;

FIG. 6 is a schematic perspective view illustrating an antifuse cell region of the first stack structure of FIG. 4;

FIG. 7 is a cross-sectional view taken along lines A1-A1′ of FIGS. 5 and A2-A2′ of FIG. 6;

FIG. 8 is a cross-sectional view taken along line B1-B1′ of FIG. 5;

FIG. 9 is an enlarged view of portion “CX1” in FIG. 7;

FIG. 10 is an enlarged view of portion s “CX2” in FIG. 7;

FIG. 11 is a layout diagram schematically illustrating a semiconductor memory device according to embodiments;

FIGS. 12 and 13 are diagrams illustrating a programming operation and a read operation of an antifuse cell included in a semiconductor memory device according to embodiments;

FIG. 14 is a cross-sectional view illustrating a semiconductor memory device according to other embodiments;

FIG. 15 is a cross-sectional view illustrating a semiconductor memory device according to other embodiments;

FIGS. 16A and 16B are cross-sectional views illustrating semiconductor memory devices according to other embodiments; and

FIGS. 17A, 17B, 18A, 18B, 19A, 19B, 20A, 20B, 21, 22, 23A, 23B, 24A and 24B are diagrams sequentially illustrating manufacturing processes of a method of manufacturing a semiconductor memory device, according to embodiments, in which FIGS. 17A, 18B, 19A, 20A, 21, 22, 23A, and 24A are diagrams corresponding to cross-sections taken along lines A1-A1′ of FIGS. 5 and A2-A2′ of FIG. 6, and FIGS. 17B, 18B, 19B, 20B, 23B, and 24B are diagrams corresponding to cross-sections taken along lines B1-B1′ of FIG. 5.

### DETAILED DESCRIPTION OF THE EMBODIMENTS

Hereinafter, embodiments are described in detail with reference to the accompanying drawings. The same reference symbols and numbers are used for identical components in the drawings, and duplicate descriptions of these are omitted.

Herein, a horizontal direction may include a first horizontal direction (an X direction) and a second horizontal direction (a Y direction) that intersect each other. A direction intersecting the first horizontal direction (the X direction) and the second horizontal direction (the Y direction) may be referred to as a vertical direction (a Z direction). Herein, a vertical level may be referred to as a height level in the vertical direction (the Z direction) of any component.

Items described in the singular herein may be provided in plural, as can be seen, for example, in the drawings. Thus, the description of a single item that is provided in plural should be understood to be applicable to the remaining plurality of items unless context indicates otherwise.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” to or “on” another element, it can be directly connected to or on the other element or intervening elements may be present. For example, when an element is being indicated as being “on” a first substrate or “on” a second substrate, that includes the element being over the first or second substrate and not necessarily in contact therewith. In contrast, when an element is referred to as “contacting” or “in contact with” another element (or using any form of the word “contact”), there are no intervening elements present at the point of contact.

As used herein, components described as being “electrically connected” are configured such that an electrical signal can be transferred from one component to the other (although such electrical signal may be attenuated in strength as it is transferred and may be selectively transferred).

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be referenced elsewhere without an ordinal number or with a different ordinal number (e.g., “second” in the specification or another claim).

Spatially relative terms, such as “beneath,” “below,” “lower,” “above,” “upper,” “top,” “bottom,” “front,” “rear,” and the like, may be used herein for ease of description to describe positional relationships, such as illustrated in the figures, for example. It will be understood that the spatially relative terms encompass different orientations of the device in addition to the orientation depicted in the figures.

Terms such as the “same,” or “equal” as used herein when referring to orientation, layout, location, shapes, sizes, compositions, amounts, or other measures do not necessarily mean an exactly identical orientation, layout, location, shape, size, composition, amount, or other measure, but are intended to encompass nearly identical orientation, layout, location, shapes, sizes, compositions, amounts, or other measures within typical variations that may occur resulting from conventional manufacturing processes.

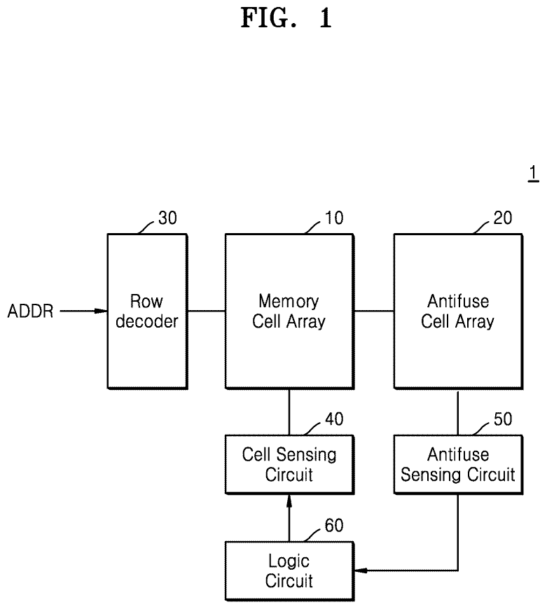

FIG. 1 is a block diagram schematically illustrating a semiconductor memory device 1 according to embodiments.

The semiconductor memory device 1 may be a semiconductor chip (i.e., a semiconductor device singulated from (e.g., cut from) a wafer).

Referring to FIG. 1, the semiconductor memory device 1 may include a memory cell array 10, an antifuse cell array 20, a row decoder 30, a cell sensing circuit 40, an antifuse sensing circuit 50, and/or a logic circuit 60.

The memory cell array 10 may include a plurality of word lines and a plurality of memory cells connected to the plurality of word lines. A plurality of memory cells may be arranged to form columns and rows. The plurality of memory cells may be formed by dynamic random-access memory (DRAM) devices. A plurality of word lines of the memory cell array 10 may be connected to the row decoder 30.

The antifuse cell array 20 may include a plurality of antifuse cells connected between a plurality of second word lines and a plurality of second bit lines. The plurality of antifuse cells may store information on fail cells included in the memory cell array 10. For example, address data of a fail cell may be electrically programmed into antifuse cells.

The row decoder 30 may select a word line by decoding an address ADDR input from the outside, and data may be read from an antifuse cell connected to the selected word line and a memory cell connected to the selected word line.

The cell sensing circuit 40 may select some of the bit lines of the memory cell array 10 in response to a control signal provided from the logic circuit 60.

The antifuse sensing circuit 50 may detect fail cell information stored in the antifuse cells of the antifuse cell array 20 connected to the selected word line and amplify the fail cell information. The antifuse sensing circuit 50 may provide a defective column address read from the antifuse cell array 20 to the logic circuit 60.

The logic circuit 60 may determine whether the address ADDR input from the outside matches an address of the fail cell, based on the address of the fail cell stored in the plurality of antifuse cells. If the address ADDR input from the outside matches the address of the fail cell, the logic circuit 60 may read out fail cell information from an antifuse cell corresponding to the fail cell and provide the fail cell information to the outside.

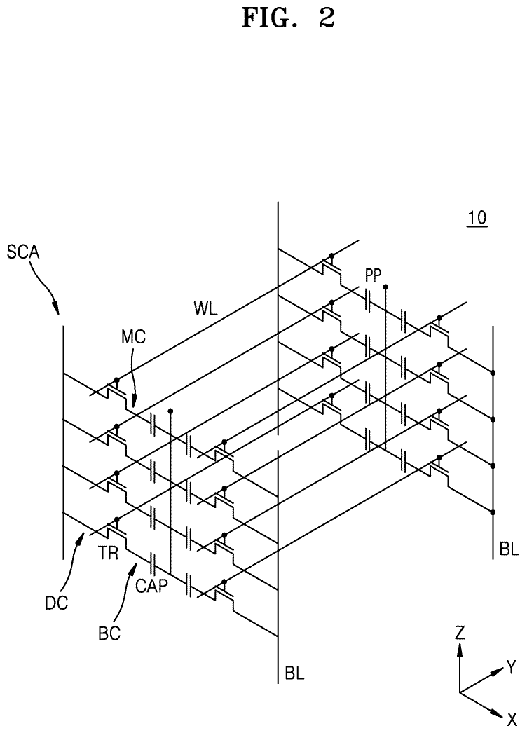

FIG. 2 is a circuit diagram illustrating the memory cell array 10 illustrated in FIG. 1.

Referring to FIG. 2, the memory cell array 10 may include a plurality of sub-cell arrays SCA. The plurality of sub-cell arrays SCA may be arranged apart from each other in the second horizontal direction (the Y direction).

The sub-cell array SCA may include a plurality of first bit lines BL, a plurality of first word lines WL, and a plurality of memory cells MC. Each of the plurality of memory cells MC may include one cell transistor TR and one cell capacitor CAP connected to the cell transistor TR. Each of the plurality of memory cells MC may have a 1 transistor-1 capacitor (1T1C) structure.

The plurality of first word lines WL may extend in the second horizontal direction (the Y direction) and be arranged apart from each other in the first horizontal direction (the X direction) and the vertical direction (the Z direction). The plurality of first bit lines BL may extend in the vertical direction (the Z direction) and be arranged apart from each other in the first horizontal direction (the X direction) and the second horizontal direction (the Y direction). One cell transistor TR may be placed between one first word line WL and one first bit line BL.

A gate of the cell transistor TR may be connected to a first word line WL, and a source of the cell transistor TR may be connected to a first bit line BL via a first contact DC. The cell transistor TR may be connected to the cell capacitor CAP through a second contact BC. A drain of the cell transistor TR may be connected to a first electrode of the cell capacitor CAP through the second contact BC, and a second electrode of the cell capacitor CAP may be connected to a first plate electrode PP.

Within the sub-cell array SCA, a plurality of cell transistors TR may be arranged at positions that overlap each other in the vertical direction (the Z direction). Within the sub-cell array SCA, the plurality of cell capacitors CAP may be arranged at positions that overlap each other in the vertical direction (the Z direction). One cell transistor TR and one cell capacitor CAP may be arranged side by side at the same vertical level, and a plurality of memory cells MC including one cell transistor TR and one cell capacitor CAP may be stacked in the vertical direction (the Z direction). A storage capacity of the sub-cell array SCA may vary depending on the number or layers of memory cells MC stacked in the vertical direction (the Z direction) (e.g., the number or layers of cell capacitors CAP).

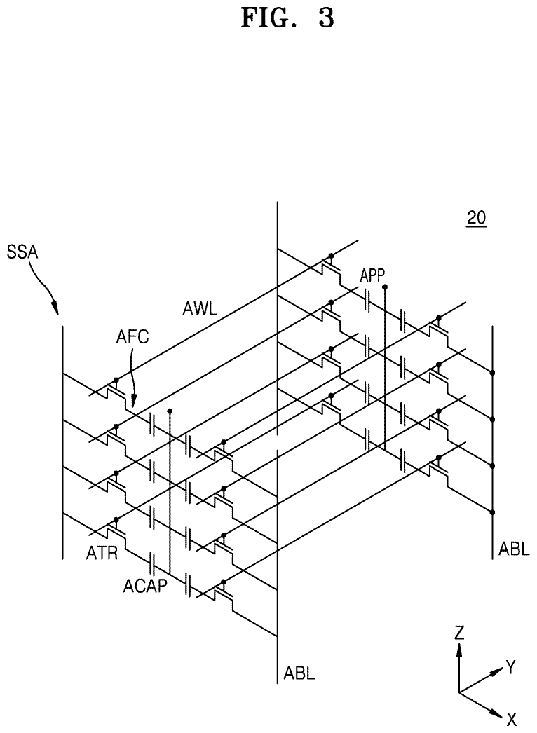

FIG. 3 is a circuit diagram illustrating the antifuse cell array 20 illustrated in FIG. 1.

Referring to FIG. 3, the antifuse cell array 20 may include a plurality of antifuse sub-cell arrays SSA. The plurality of antifuse sub-cell arrays SSA may be arranged apart from each other in the second horizontal direction (the Y direction).

Each antifuse sub-cell array SSA may include a plurality of second bit lines ABL, a plurality of second word lines AWL, and a plurality of antifuse cells AFC. Each of the plurality of antifuse cells AFC may include a second cell transistor ATR and an antifuse capacitor ACAP connected thereto. Each of the plurality of antifuse cells AFC may have a 1T1C structure.

A plurality of second word lines AWL may extend in the second horizontal direction (the Y direction) and be arranged apart from each other in the first horizontal direction (the X direction) and the vertical direction (the Z direction). The plurality of second bit lines ABL may extend in the vertical direction (the Z direction) and be arranged apart from each other in the first horizontal direction (the X direction) and the second horizontal direction (the Y direction). One second cell transistor ATR may be placed between one second word line AWL and one second bit line ABL.

A gate of the second cell transistor ATR may be connected to the second word line AWL, and a source of the second cell transistor ATR may be connected to the second bit line ABL. A first electrode of the antifuse capacitor ACAP may be connected to a drain of a second cell transistor ATR, and a second electrode of the antifuse capacitor ACAP may be connected to a second plate electrode APP.

Within the antifuse sub-cell array SSA, the plurality of antifuse cells AFC may be arranged at positions that overlap each other in the vertical direction (the Z direction). Within the antifuse sub-cell array SSA, a plurality of antifuse capacitors ACAP may be positioned to overlap each other in the vertical direction (the Z direction). One second cell transistor ATR and one antifuse capacitor ACAP may be arranged side by side at the same vertical level, and the plurality of antifuse cells AFC including one second cell transistor ATR and one antifuse capacitor ACAP may be stacked in the vertical direction (the Z direction).

In some embodiments, the plurality of antifuse cells AFC may be formed together within at least a portion of a process for forming the cell transistor TR within the memory cell array 10. The plurality of antifuse cells AFC may have a structure that is identical to or similar to the plurality of memory cells MC in the memory cell array 10.

In some embodiments, the number (e.g., number of layers) of antifuse cells AFC stacked in the vertical direction (the Z direction) and the number of antifuse capacitors ACAP may be equal to the number of memory cells MC stacked in the vertical direction (the Z direction) and the number of cell capacitors CAP. In some embodiments, a vertical level of each of the plurality of antifuse cells AFC and the plurality of antifuse capacitors ACAP may be equal to a vertical level of each of the plurality of corresponding memory cells MC and the plurality of cell capacitors CAP. In some other embodiments, the number (e.g., number of layers) of antifuse cells AFC stacked in the vertical direction (the Z direction) may be less than the number (e.g., number of layers) of cell capacitors CAP stacked in the vertical direction (the Z direction).

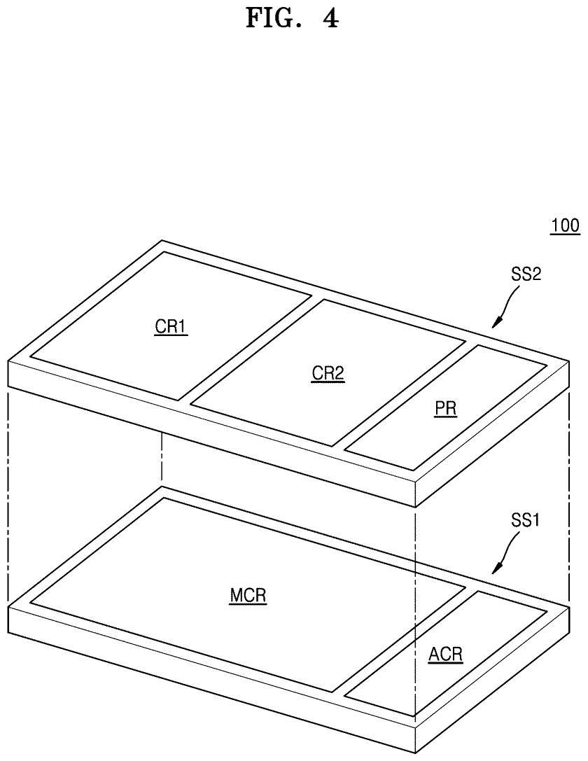

FIG. 4 is a perspective view illustrating a semiconductor memory device 100 according to embodiments.

The semiconductor memory device 100 may have a structure in which the first stack structure SS1 and a second stack structure SS2 are stacked in the vertical direction. For example, the first stack structure SS1 may be positioned at a vertical level different from that of the second stack structure SS2. In FIG. 4, for convenience of understanding, the first stack structure SS1 is shown as being separated from the second stack structure SS2, but the semiconductor memory device 100 may have a structure in which a bottom surface of the second stack structure SS2 is attached to an upper surface of the first stack structure SS1.

The first stack structure SS1 and/or the second stack structure SS2 may be a wafer or a portion of a wafer.

The first stack structure SS1 may include a memory cell region MCR and an antifuse cell region ACR. The memory cell region MCR may be a region in which the memory cell array 10 described above with reference to FIGS. 1 and 2 is placed. For example, first bit lines, first word lines, and memory cells may be arranged within the memory cell region MCR. The antifuse cell region ACR may be a region in which the antifuse cell array 20 described above with reference to FIGS. 1 and 3 is placed. The antifuse cell region ACR may be placed on one side of the memory cell region MCR. For example, second bit lines, second word lines, and antifuse cells may be placed within the antifuse cell region ACR.

In example embodiments, the first stack structure SS1 includes at the memory cell region MCR, a first semiconductor pattern 120 extending on the first substrate 110 in a first horizontal direction (the X direction), a word line WL surrounding the first semiconductor pattern 120 and extending in a second horizontal direction (the Y direction) intersecting the first horizontal direction (the X direction), and a first bit line BL connected to a first end portion 126 of the first semiconductor pattern 120 and extending in a vertical direction (the Z direction) intersecting the first horizontal direction (the X direction). According to examples, the cell capacitor CAP is connected to a second end portion 128 of the first semiconductor pattern 120 opposite to the first end portion 126 of the first semiconductor pattern 120, and extends in the first horizontal direction (the X direction).

In example embodiments, the first stack structure SS1 includes at the antifuse cell region ACR, a second semiconductor pattern 220 extending on the first substrate 110 in a first horizontal direction (the X direction), an antifuse word line AWL (or second word line) surrounding the second semiconductor pattern 220 and extending in a second horizontal direction (the Y direction) intersecting the first horizontal direction (the X direction), and an antifuse bit line ABL (or second bit line) connected to a first end portion 226 of the second semiconductor pattern 220 and extending in a vertical direction (the Z direction) intersecting the first horizontal direction (the X direction). According to examples, the antifuse capacitor ACAP is connected to a second end portion 228 of the second semiconductor pattern 220 opposite to the first end portion 226 of the second semiconductor pattern 220, and extends in the first horizontal direction (the X direction).

The second stack structure SS2 may include a first core region CR1, a second core region CR2, and a peripheral circuit region PR. The first core region CR1 and the second core region CR2 may be positioned to vertically overlap the memory cell region MCR and may include core circuits electrically connected to the memory cell region MCR. In one or more embodiments the first core region CR1 may include sense amplifiers, which may be electrically connected to bit lines included in the first stack structure SS1. In one or more embodiments the second core region CR2 may include sub-word line drivers, and these sub-word line drivers may be electrically connected to word lines included in the first stack structure SS1.

The peripheral circuit region PR may be positioned to vertically overlap the antifuse cell region ACR. The peripheral circuit region PR may include a control signal-generating circuit for controlling a sub-word line driver, a control signal-generating circuit for controlling a sense amplifier, and an antifuse cell sensing circuit for controlling an antifuse cell array placed in the antifuse cell region ACR. In addition, the peripheral circuit region PR may further include a voltage generator that provides an operating voltage to the sense amplifier, the sub-word line driver, the antifuse cell sensing circuit, etc.

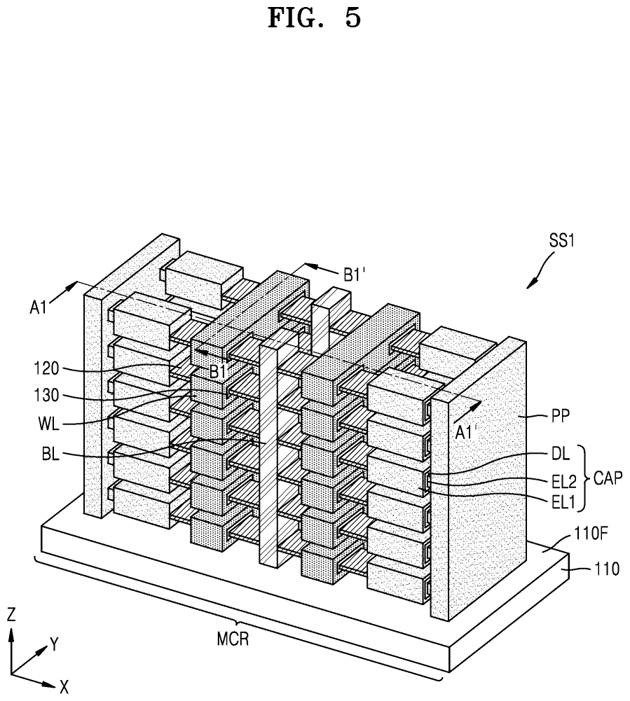

FIG. 5 is a schematic perspective view illustrating the memory cell region MCR of the first stack structure SS1 of FIG. 4.

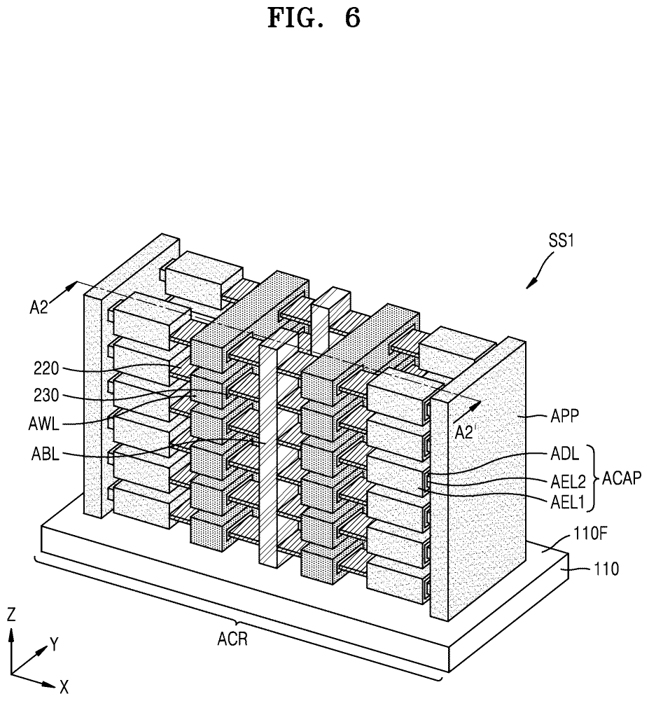

FIG. 6 is a schematic perspective view illustrating the antifuse cell region ACR of the first stack structure SS1 of FIG. 4.

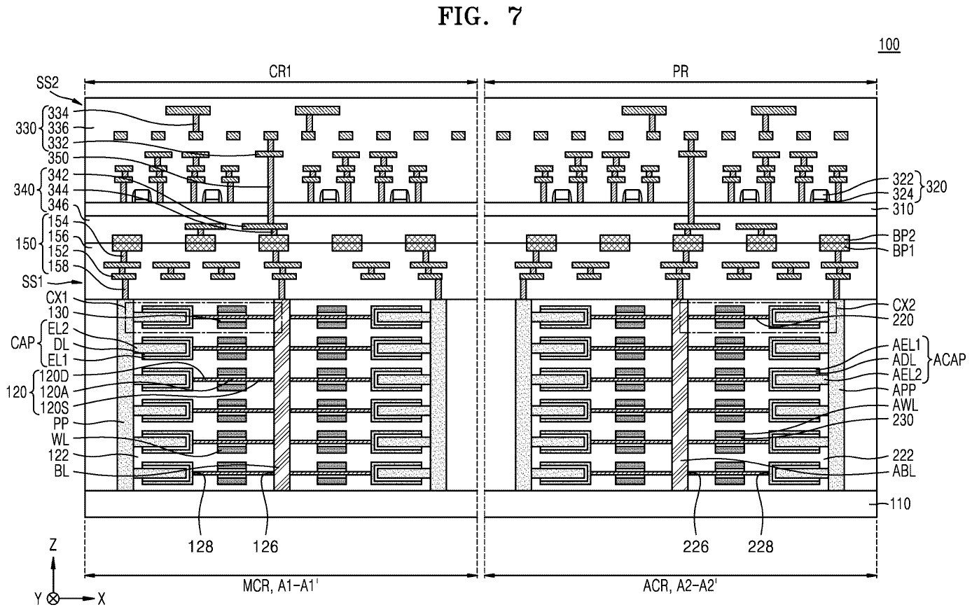

FIG. 7 is a cross-sectional view taken along lines A1-A1′ of FIGS. 5 and A2-A2′ of FIG. 6.

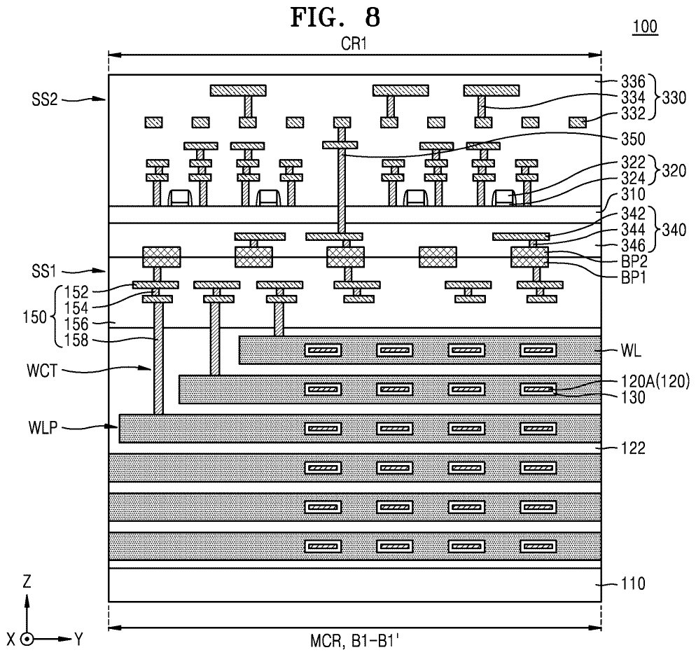

FIG. 8 is a cross-sectional view taken along line B1-B1′ of FIG. 5.

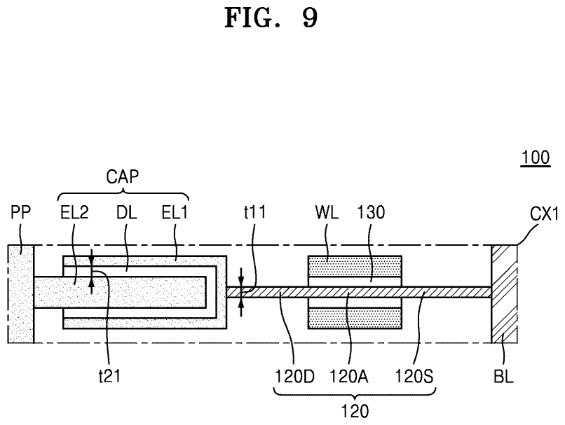

FIG. 9 is an enlarged view of portion “CX1” in FIG. 7.

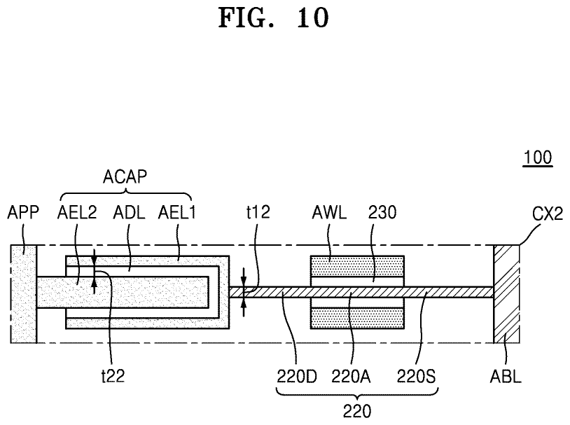

FIG. 10 is an enlarged view of portion “CX2” in FIG. 7.

Referring to FIGS. 5 to 10, the semiconductor memory device 100 may include the first stack structure SS1 and the second stack structure SS2, and the second stack structure SS2 may be bonded to the first stack structure SS1 by first and second bonding pads BP1 and BP2.

The first stack structure SS1 may include the memory cell region MCR and the antifuse cell region ACR.

The first stack structure SS1 may include a plurality of first semiconductor patterns 120, the plurality of first bit lines BL, the plurality of first word lines WL, and the cell capacitor CAP arranged on a first substrate 110 in the memory cell region MCR.

In one or more embodiments the first substrate 110 may be a base substrate and formed of a crystalline semiconductor material, such as Si, Ge, or SiGe. In one or more embodiments the first substrate 110 may be a silicon-on-insulator (SOI) substrate or a germanium-on-insulator (GeOI) substrate.

Herein, the first horizontal direction (the X direction) and the second horizontal direction (the Y direction) may intersect each other and be directions parallel to an upper surface 110F of the first substrate 110, and the vertical direction (the Z direction) may be a direction intersecting the first horizontal direction (the X direction) and the second horizontal direction (the Y direction).

The vertical direction (the Z direction) may be perpendicular to the upper surface 110F of the first substrate 110.

In the memory cell region MCR, the plurality of first semiconductor patterns 120 may be arranged on the first substrate 110, extend in the first horizontal direction (the X direction), and be apart from each other in the vertical direction (the Z direction).

In one or more embodiments the plurality of first semiconductor patterns 120 may include, for example, an undoped semiconductor material or a doped semiconductor material. In some embodiments, the plurality of first semiconductor patterns 120 may include or be polysilicon. In some embodiments, the plurality of first semiconductor patterns 120 may include an amorphous metal oxide, a polycrystalline metal oxide, or a combination of the amorphous metal oxide and the polycrystalline metal oxide, and may include, for example, at least one of In—Ga-based oxide (IGO), In—Zn-based oxide (IZO), or In—Ga—Zn-based oxide (IGZO). In some other embodiments, the plurality of first semiconductor patterns 120 may include a 2D material semiconductor, and the 2D material semiconductor may include, for example, MoS₂, WSe₂, graphene, carbon nano tube, or combinations thereof.

In one or more embodiments the plurality of first semiconductor patterns 120 may have a line shape or a bar shape extending in the first horizontal direction (the X direction). In one or more embodiments each semiconductor pattern 120 of the first semiconductor patterns 120 may include a channel region 120A and a first impurity region 120S and a second impurity region 120D arranged in the first horizontal direction (the X direction) with the channel region 120A therebetween. The first impurity region 120S may be connected to the first bit line BL, and the second impurity region 120D may be connected to the cell capacitor CAP. An ohmic metal layer including a metal silicide or the like may be further formed between the first impurity region 120S and the first bit line BL and between the second impurity region 120D and the cell capacitor CAP.

The plurality of first word lines WL may be arranged on the upper and bottom surfaces of the plurality of first semiconductor patterns 120, extend in the second horizontal direction (the Y direction), and be apart from each other in the vertical direction (the Z direction). One of the plurality of first word lines WL may surround a first semiconductor pattern 120 of the plurality of first semiconductor patterns 120 apart from each other in the second horizontal direction (the Y direction) and may extend in the second horizontal direction (the Y direction). Among the plurality of first word lines WL, two first word lines WL apart from each other in the vertical direction (the Z direction) may be positioned to overlap each other in the vertical direction (the Z direction).

In one or more embodiments the plurality of first word lines WL may include at least one of a doped semiconductor material (e.g., doped silicon, doped germanium, etc.), a conductive metal nitride (e.g., titanium nitride, tantalum nitride, etc.), a metal (e.g., tungsten, titanium, tantalum, etc.), and/or a metal-semiconductor compound (e.g., tungsten silicide, cobalt silicide, titanium silicide, etc.).

In one or more embodiments a first gate insulating layer 130 may be located between a first word line WL and a first semiconductor pattern 120. The first gate insulating layer 130 may include at least one selected from a high-k dielectric material and a ferroelectric material having a higher dielectric constant than that of silicon oxide. In some embodiments, the first gate insulating layer 130 may include at least one selected from hafnium oxide (HfO), hafnium silicate (HfSiO), hafnium oxynitride (HfON), hafnium silicon oxynitride (HfSiON), lanthanum oxide (LaO), lanthanum aluminum oxide (LaAIO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium bismuth tantalate (STB), bismuth iron oxide (BFO), strontium titanium oxide (SrTiO), yttrium oxide (YO), aluminum oxide (AIO), or lead scandium tantalum oxide (PbScTaO).

The plurality of first bit lines BL may be arranged to extend in the vertical direction (the Z direction) and apart from each other in the second horizontal direction (the Y direction) on the first substrate 110. The plurality of first bit lines BL may be any one of a doped semiconductor material, a conductive metal nitride, a metal, and/or a metal-semiconductor compound.

The cell capacitor CAP may include a first electrode EL1, a capacitor dielectric layer DL, and a second electrode EL2. The first electrode EL1 may extend in the first horizontal direction (the X direction) and be apart from each other in the vertical direction (the Z direction). The first electrode EL1 may have an internal space (not shown) extending in the first horizontal direction (the X direction), and the internal space may be filled with the capacitor dielectric layer DL and the second electrode EL2. For example, the first electrode EL1 may have a cup shape rotated by 90 degrees.

The capacitor dielectric layer DL may include at least one selected from a high-k dielectric material and a ferroelectric material having a dielectric constant higher than that of silicon oxide. In some embodiments, the capacitor dielectric layer DL includes at least one selected from hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium bismuth tantalate (STB), bismuth iron oxide (BFO), strontium titanium oxide (SrTiO), yttrium oxide (YO), aluminum oxide (AIO), or lead scandium tantalum oxide (PbScTaO).

The second electrode EL2 may fill the internal space of the first electrode EL1, and the capacitor dielectric layer DL may be located between the internal space of the first electrode EL1 and the second electrode EL2.

The first electrode EL1 and the second electrode EL2 may include a doped semiconductor material, a conductive metal nitride, such as titanium nitride, tantalum nitride, niobium nitride or tungsten nitride, a metal, such as ruthenium, iridium, titanium, or tantalum, and/or a conductive metal oxide, such as iridium oxide or niobium oxide.

The first plate electrode PP may be located to extend in the vertical direction (the Z direction) and the second horizontal direction (the Y direction) on one side of the cell capacitor CAP. The second electrode EL2 of the cell capacitor CAP may be electrically connected to the first plate electrode PP. For example, the first plate electrode PP may be commonly connected to a plurality of second electrodes EL2 apart from each other in the vertical direction (the Z direction) and a plurality of second electrodes EL2 apart from each other in the second horizontal direction (the Y direction).

A first mold insulating layer 122 may be located between two adjacent first semiconductor patterns 120 apart from each other in the vertical direction (the Z direction), between two adjacent first word lines WL apart from each other in the vertical direction (the Z direction), and between two adjacent cell capacitors CAP apart from each other in the vertical direction (the Z direction). In addition, the first mold insulating layer 122 may also be located between two first bit lines BL apart from each other in the second horizontal direction (the Y direction).

In one or more embodiments the first mold insulating layer 122 may include silicon oxide, silicon oxynitride, silicon nitride, carbon-containing silicon oxide, carbon-containing silicon oxynitride, carbon-containing silicon nitride, or combinations thereof. In one or more embodiments the first mold insulating layer 122 may include a plurality of insulating layers. In examples, insulating material layers formed between the plurality of first bit lines BL, between the plurality of first word lines WL, between the plurality of first semiconductor patterns 120, and between the plurality of cell capacitors CAP according to a manufacturing process employed to form a three-dimensional (3D) structure may be collectively referred to as the first mold insulating layer 122.

The first stack structure SS1 may include a plurality of second semiconductor patterns 220, the plurality of second bit lines ABL, the plurality of second word lines AWL, and the plurality of antifuse capacitors ACAP arranged on the first substrate 110 in the antifuse cell region ACR.

In the antifuse cell region ACR, the plurality of second semiconductor patterns 220 may be arranged on the first substrate 110, extend in the first horizontal direction (the X direction), and be apart from each other in the vertical direction (the Z direction). In one or more embodiments the plurality of second semiconductor patterns 220 may include, for example, an undoped semiconductor material or a doped semiconductor material. The plurality of second semiconductor patterns 220 may include a material identical to or similar to that of the plurality of first semiconductor patterns 120. In some embodiments, the plurality of second semiconductor patterns 220 may include or be polysilicon. In some embodiments, the plurality of second semiconductor patterns 220 may include or be an amorphous metal oxide, a polycrystalline metal oxide, or a combination of the amorphous metal oxide and the polycrystalline metal oxide, and may include, for example, at least one of In—Ga-based oxide (IGO), In—Zn-based oxide (IZO), or In—Ga—Zn-based oxide (IGZO). In some other embodiments, the plurality of second semiconductor patterns 220 may be a 2D material semiconductor, and the 2D material semiconductor may include, for example, MoS₂, WSe₂, graphene, carbon nano tube, or combinations thereof.

In one or more embodiments the plurality of second semiconductor patterns 220 may have a line shape or a bar shape extending in the first horizontal direction (the X direction). In one or more embodiments each second semiconductor pattern 220 of the second semiconductor patterns 220 may include an antifuse channel region 220A and a first antifuse impurity region 220S and a second antifuse impurity region 220D arranged in the first horizontal direction (the X direction) with the antifuse channel region 220A therebetween. The first antifuse impurity region 220S may be connected to the second bit line ABL, and the second antifuse impurity region 220D may be connected to the antifuse capacitor ACAP. An ohmic metal layer including metal silicide or the like may be further formed between the first antifuse impurity region 220S and the second bit line ABL and between the second antifuse impurity region 220D and the antifuse capacitor ACAP.

In one or more embodiments the plurality of second semiconductor patterns 220 may be formed simultaneously during a formation process of the plurality of first semiconductor patterns 120. For example, the plurality of first semiconductor patterns 120 may be formed in the memory cell region MCR and the plurality of second semiconductor patterns 220 may be formed in the antifuse cell region ACR by alternately stacking a semiconductor layer and a sacrificial layer on the first substrate 110 and then removing portions of the semiconductor layer.

In one or more embodiments a thickness t12 of the plurality of second semiconductor patterns 220 in the vertical direction (the Z direction) may be equal to a thickness t11 of the plurality of first semiconductor patterns 120 in the vertical direction (the Z direction). In addition, the plurality of second semiconductor patterns 220 may be arranged at the same vertical level as that of the plurality of first semiconductor patterns 120, and the number of second semiconductor patterns 220 arranged in the vertical direction (the Z direction) may be the same as the number of first semiconductor patterns 120 arranged in the vertical direction (the Z direction).

The plurality of second word lines AWL may be arranged on the upper and bottom surfaces of the plurality of second semiconductor patterns 220, extend in the second horizontal direction (the Y direction), and be apart from each other in the vertical direction (the Z direction). One of the plurality of second word lines AWL may surround the plurality of second semiconductor patterns 220 apart from each other in the second horizontal direction (the Y direction) and may extend in the second horizontal direction (the Y direction). Among the plurality of second word lines AWL, two second word lines AWL apart from each other in the vertical direction (the Z direction) may be positioned to overlap each other in the vertical direction (the Z direction).

In one or more embodiments the plurality of second word lines AWL may include at least one of a doped semiconductor material (e.g., doped silicon, doped germanium, etc.), a conductive metal nitride (e.g., titanium nitride, tantalum nitride, etc.), a metal (e.g., tungsten, titanium, tantalum, etc.), and/or a metal-semiconductor compound (e.g., tungsten silicide, cobalt silicide, titanium silicide, etc.).

In one or more embodiments a second gate insulating layer 230 may be located between the second word line AWL and the second semiconductor pattern 220. The second gate insulating layer 230 may include at least one selected from a high-k dielectric material and/or a ferroelectric material having a higher dielectric constant than that of silicon oxide. In some embodiments, the second gate insulating layer 230 includes at least one material selected from hafnium oxide (HfO), hafnium silicate (HfSiO), hafnium oxynitride (HfON), hafnium silicon oxynitride (HfSiON), lanthanum oxide (LaO), lanthanum aluminum oxide (LaAIO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium bismuth tantalate (STB), bismuth iron oxide (BFO), strontium titanium oxide (SrTiO), yttrium oxide (YO), aluminum oxide (AlO), and/or lead scandium tantalum oxide (PbScTaO).

The plurality of second bit lines ABL may extend in the vertical direction (the Z direction) and be apart from each other in the second horizontal direction (the Y direction) on the first substrate 110. The plurality of second bit lines ABL may be any one of a doped semiconductor material, a conductive metal nitride, a metal, and a metal-semiconductor compound.

The antifuse cell capacitor CAP may include a first antifuse electrode AEL1, an antifuse capacitor dielectric layer ADL, and a second antifuse electrode AEL2. The first antifuse electrode AEL1 may extend in the first horizontal direction (the X direction) and be apart from each other in the vertical direction (the Z direction). The first antifuse electrode AEL1 may have an internal space (not shown) extending in the first horizontal direction (the X direction), and the internal space may be filled with the antifuse capacitor dielectric layer ADL and the second antifuse electrode AEL2. For example, the first antifuse electrode AEL1 may have a cup shape rotated by 90 degrees.

The antifuse capacitor dielectric layer ADL may include at least one selected from a high-k dielectric material and/or a ferroelectric material having a dielectric constant higher than that of silicon oxide. In some embodiments, the antifuse capacitor dielectric layer ADL may include at least one selected from hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium bismuth tantalate (STB), bismuth iron oxide (BFO), strontium titanium oxide (SrTiO), yttrium oxide (YO), aluminum oxide (AlO), and/or lead scandium tantalum oxide (PbScTaO).

In one or more embodiments the capacitor dielectric layer DL included in the cell capacitor CAP in the memory cell region MCR may be formed simultaneously during the same process as that of the antifuse capacitor dielectric layer ADL included in the antifuse capacitor ACAP in the antifuse cell region ACR. In some embodiments, the capacitor dielectric layer DL and the antifuse capacitor dielectric layer ADL may be the same material. In some embodiments, a thickness t21 of the capacitor dielectric layer DL in the vertical direction (the Z direction) may be equal to a thickness t22 of the antifuse capacitor dielectric layer ADL in the vertical direction (the Z direction).

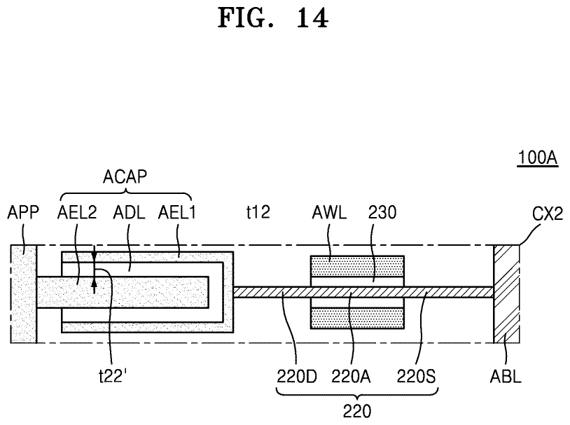

However, the capacitor dielectric layer DL included in the cell capacitor CAP in the memory cell region MCR and the antifuse capacitor dielectric layer ADL included in the antifuse capacitor ACAP in the antifuse cell region ACR are not limited to being formed simultaneously during the same process but may be formed through different processes separate from each other. Because the antifuse capacitor ACAP in the antifuse cell region ACR has to form a hard breakdown path that electrically connects the first antifuse electrode AEL1 to the second antifuse electrode AEL2 by breaking down the antifuse capacitor dielectric layer ADL for a programming operation of the antifuse cell AFC when some of the memory cells in the memory cell region MCR are defective, the antifuse capacitor dielectric layer ADL may be a different thickness and/or a different material than those of the capacitor dielectric layer DL included in the cell capacitor CAP in the memory cell region MCR depending on a breakdown voltage to be set. An embodiment in which the capacitor dielectric layer DL included in the cell capacitor CAP in the memory cell region MCR and the antifuse capacitor dielectric layer ADL included in the antifuse capacitor ACAP in the antifuse cell region ACR have different thicknesses and/or different materials is described in detail below with reference to FIG. 14.

In one or more embodiments, the plurality of antifuse capacitors ACAP may be arranged at the same vertical level as the plurality of cell capacitors CAP, and the number of antifuse capacitors ACAP arranged in the vertical direction (the Z direction) may be equal to the number of cell capacitors CAP arranged in the vertical direction (the Z direction).

A second plate electrode APP may be arranged to extend in the vertical direction (the Z direction) and the second horizontal direction (the Y direction) on one side of the antifuse capacitor ACAP. The second antifuse electrode AEL2 of the antifuse capacitor ACAP may be electrically connected to the second plate electrode APP. For example, the second antifuse electrode AEL2 of the antifuse capacitor ACAP may be commonly connected to the plurality of second antifuse electrodes AEL2 apart from each other in the vertical direction (the Z direction) and the plurality of second antifuse electrodes AEL2 apart from each other in the second horizontal direction (the Y direction).

A second mold insulating layer 222 may be located between two adjacent second semiconductor patterns 220 apart from each other in the vertical direction (the Z direction), between two adjacent second word lines AWL apart from each other in the vertical direction (the Z direction), and between two adjacent antifuse capacitors ACAP apart from each other in the vertical direction (the Z direction). In addition, the second mold insulating layer 222 may also be placed between two second bit lines ABL apart from each other in the second horizontal direction (the Y direction).

In one or more embodiments the second mold insulating layer 222 may include silicon oxide, silicon oxynitride, silicon nitride, carbon-containing silicon oxide, carbon-containing silicon oxynitride, carbon-containing silicon nitride, or combinations thereof. In one or more embodiments the second mold insulating layer 222 may include a plurality of insulating layers. In examples, insulating material layers formed between the plurality of second bit lines ABL, between the plurality of second word lines AWL, between the plurality of second semiconductor patterns 220, and between the plurality of antifuse capacitors ACAP according to the manufacturing process employed to form a 3D structure may be collectively referred to as the second mold insulating layer 222.

An upper interconnection structure 150 may be placed in the memory cell region MCR and the antifuse cell region ACR. The upper interconnection structure 150 may include an interconnection layer 152, a via 154, and an insulating layer 156. The upper interconnection structure 150 may further include a contact 158 electrically connected to the first bit line BL, the first word line WL, and the first plate electrode PP. In addition, the first bonding pad BP1 may be formed on the upper interconnection structure 150 and positioned in the same plane as the uppermost surface of the insulating layer 156.

The second stack structure SS2 may include a second substrate 310, a peripheral circuit transistor 320 disposed on the second substrate 310, a front interconnection structure 330 covering the peripheral circuit transistor 320 on an upper surface of the second substrate 310, and a rear interconnection structure 340 disposed on a bottom surface of the second substrate 310. The front interconnection structure 330 may include an interconnection layer 332, a via 334, and an insulating layer 336, and the rear interconnection structure 340 may include an interconnection layer 342, a via 344, and an insulating layer 346.

The rear interconnection structure 340 may include the second bonding pad BP2 placed in the same plane as a bottom surface of the insulating layer 346, and the first stack structure SS1 may be bonded to the second stack structure SS2 as the first bonding pad BP1 is connected to the second bonding pad BP2. In one or more embodiments the first stack structure SS1 may be attached to the second stack structure SS2 in a copper-oxide hybrid bonding manner. In one or more embodiments the first bonding pad BP1 and the second bonding pad BP2 may include copper or a copper alloy. An interface between the insulating layer 156 of the upper interconnection structure 150 and the insulating layer 346 of the rear interconnection structure 340 may extend flatly and may be placed in the same plane as an interface between the first bonding pad BP1 and the second bonding pad BP2.

In one or more embodiments the peripheral circuit transistor 320 may include a gate electrode 322 and a gate insulating layer 324 arranged on an active region of the second substrate 310. In one or more embodiments the peripheral circuit transistor 320 disposed in the first core region CR1 may include sense amplifiers, and the sense amplifiers may be electrically connected to the plurality of first bit lines BL included in the first stack structure SS1. The peripheral circuit transistor 320 disposed in the second core region CR2 (see FIG. 4) may include sub-word line drivers, and these sub-word line drivers may be electrically connected to the plurality of first word lines WL included in the first stack structure SS1.

In one or more embodiments the second stack structure SS2 may further include a through-via 350 penetrating the second substrate 310, the interconnection layer 332 included in the front interconnection structure 330 may be electrically connected to the interconnection layer 332 included in the rear interconnection structure 340 by the through-via 350, and the interconnection layer 332 included in the rear interconnection structure 340 may be electrically connected to the interconnection layer 332 included in the front interconnection structure 330 through the first bonding pad BP1 and the second bonding pad BP2.

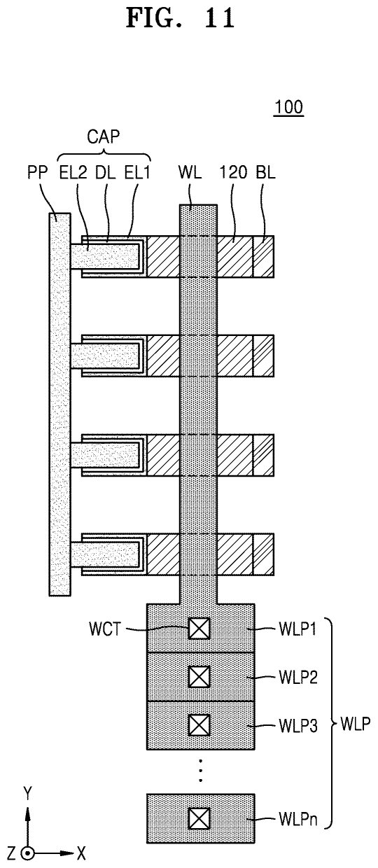

FIG. 11 is a layout diagram schematically illustrating the semiconductor memory device 100 according to embodiments.

Referring to FIG. 11 together with FIG. 8, the first word line WL may extend in the second horizontal direction (the Y direction) to intersect the first horizontal direction (the X direction), which is an extension direction of the first semiconductor pattern 120. A word line pad WLP may be placed at an end portion of the first word line WL. As illustrated in FIG. 11, a plurality of word line pads WLP may be arranged sequentially in the second horizontal direction (the Y direction), and as illustrated in FIG. 8, the plurality of word line pads WLP may be arranged in a step shape in the second horizontal direction (the Y direction).

In one or more embodiments a word line pad WLP1 connected to the first word line WL positioned at the top, a second word line pad WLP2 connected to the first word line WL positioned below the first word line WL at the top, and a third word line WLP3 pad connected to the first word line WL positioned below the two top first word lines WL may be sequentially arranged in the second horizontal direction (the Y direction), such that a word line pad WLPn connected to an n-th first word line WL from the top may be placed in the second horizontal direction (the Y direction).

A word line contact WCT may be placed on an upper surface of each word line pad WLP, and the first word line WL may be electrically connected to the upper interconnection structure 150 by the word line contact WCT.

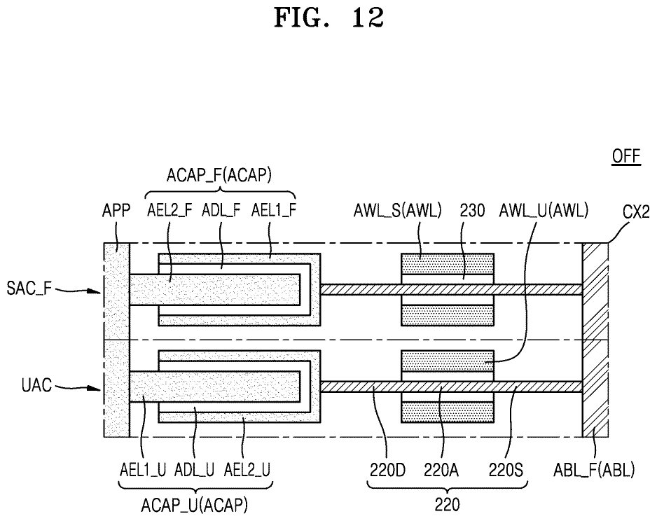

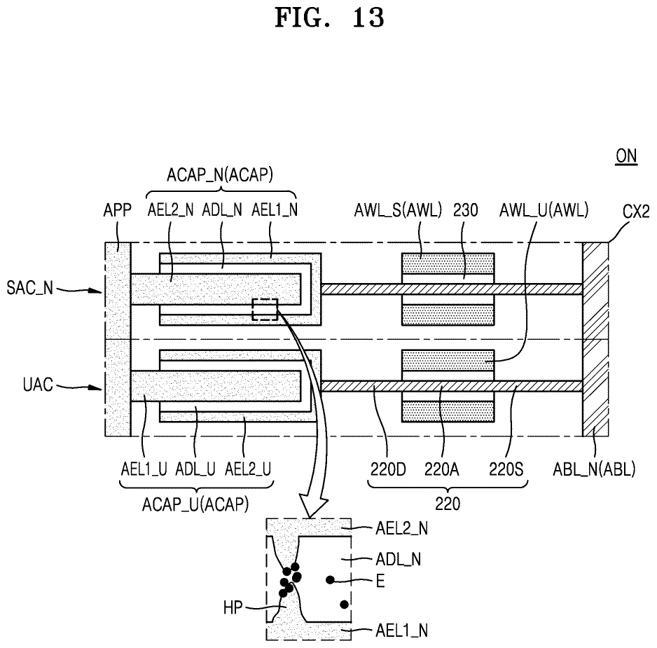

FIGS. 12 and 13 are diagrams illustrating a programming operation and a read operation of an antifuse cell included in the semiconductor memory device 100 according to embodiments.

In detail, FIG. 12 is a diagram illustrating programming and reading an “OFF” cell among antifuse cells, and FIG. 13 is a diagram illustrating programming and reading an “ON” cell among antifuse cells.

A programming operation of the antifuse cell is first described with reference to FIGS. 12 and 13.

Herein, among antifuse cells, an antifuse cell programmed as an “OFF” cell is referred to as an OFF antifuse cell SAC_F, an antifuse cell programmed as an “ON” cell is referred to as an ON antifuse cell SAC_N, and an antifuse cell that is not programmed is referred to as an unselected antifuse cell UAC. The OFF antifuse cell SAC_F and ON antifuse cell SAC_N may be electrically connected to the same second word line AWL. For example, the OFF antifuse cell SAC_F may be apart from the ON antifuse cell SAC_N in the second horizontal direction (the Y direction). The OFF antifuse cell SAC_F, the ON antifuse cell SAC_N, and the unselected antifuse cell UAC may be electrically connected to different second word lines AWL. For example, the OFF antifuse cell SAC_F, the ON antifuse cell SAC_N, and the unselected antifuse cell UAC may be apart from each other in the vertical direction (the Z direction). Herein, the second word line AWL to which the OFF antifuse cell SAC_F and the ON antifuse cell SAC_N are electrically connected may be referred to as a selected word line AWL_S, and the second word line AWL to which the unselected antifuse cell UAC is electrically connected may be referred to as an unselected word line AWL_U. The selected word line AWL_S may be apart from the unselected word line AWL_U in the vertical direction (the Z direction).

The second bit line ABL to which the OFF antifuse cell SAC_F is electrically connected may be different from the second bit line ABL to which the ON antifuse cell SAC_N is electrically connected. Herein, the second bit line ABL to which the OFF antifuse cell SAC_F is electrically connected may be referred to as an OFF bit line ABL_F, and the second bit line ABL to which the ON antifuse cell SAC_N is electrically connected may be referred to as an ON bit line ABL_N. The OFF bit line ABL_F may be apart from the ON bit line ABL_N in the second horizontal direction (the Y direction).

To perform programming operations of the OFF antifuse cell SAC_F and the ON antifuse cell SAC_N, a breakdown voltage Vₐₙₜᵢ may be applied to the second plate electrode APP to which the OFF antifuse cell SAC_F, the ON antifuse cell SAC_N and the unselected antifuse cell UAC are electrically connected. The breakdown voltage Vₐₙₜᵢ may be a relatively high voltage. In addition, a peak-to-peak voltage Vₚₚ may be applied to the selected word line AWL_S to which the OFF antifuse cell SAC_F and the ON antifuse cell SAC_N are electrically connected, and OV may be applied to the unselected word line AWL_U electrically connected to the unselected antifuse cell UAC.

As illustrated in FIG. 12, when the peak-to-peak voltage Vₚₚ is applied to the OFF bit line ABL_F electrically connected to the OFF antifuse cell SAC_F, the peak-to-peak voltage Vₚₚ is applied to the selected word line AWL_S electrically connected to the OFF antifuse cell SAC_F, and thus, a potential difference between the selected word line AWL_S and the OFF bit line ABL_F becomes “0” and a first antifuse electrode AEL1_F of an OFF antifuse capacitor ACAP_F of the OFF antifuse cell SAC_F is electrically floated, and the antifuse capacitor dielectric layer ADL_F is not hard broken down, so a hard breakdown path (HP, see FIG. 13) may not be formed. As illustrated in FIG. 13, when 0 V is applied to the ON bit line ABL_N electrically connected to the ON antifuse cell SAC_N, a potential difference between the selected word line AWL_S and the ON bit line ABL_N becomes the peak-to-peak voltage Vₚₚ, 0 V is applied to the first antifuse electrode AEL1_N of the ON antifuse capacitor ACAP_N of the ON antifuse cell SAC_N, and the breakdown voltage Vₐₙₜᵢ is applied to the second antifuse electrode AEL2_N so that an antifuse capacitor dielectric layer ADL_N may be hard broken down and a hard breakdown path HP may be formed. Along the hard breakdown path HP, electrons E may move, which may result in a relatively large leakage current.

Next, a read operation of the antifuse cell is described.

To perform a read operation of the OFF antifuse cell SAC_F and the ON antifuse cell SAC_N, a voltage relatively less than the breakdown voltage Vₐₙₜᵢ, for example, the peak-to-peak voltage Vₚₚ or a value (Vₚₚ-Vt) obtained by subtracting a threshold voltage Vt of the OFF antifuse cell SAC_F or the ON antifuse cell SAC_N from the peak-to-peak voltage Vₚₚ may be applied to the second plate electrode APP to which the OFF antifuse cell SAC_F, the ON antifuse cell SAC_N, and the unselected antifuse cell UAC are electrically connected.

In addition, the peak-to-peak voltage Vₚₚ may be applied to the selected word line AWL_S to which the OFF antifuse cell SAC_F and the ON antifuse cell SAC_N are connected, and OV may be applied to the unselected word line AWL_U electrically connected to an unselected antifuse cell UAC.

As illustrated in FIG. 12, when OV is applied to the OFF bit line ABL_F electrically connected to the OFF antifuse cell SAC_F, a relatively small leakage current may be sensed. This may be due to the fact that a hard breakdown path HP (See FIG. 13) is not formed in the antifuse capacitor dielectric layer ADL_F of the OFF antifuse capacitor ACAP_F of the OFF antifuse cell SAC_F.

As illustrated in FIG. 13, when 0 V is applied to the ON bit line ABL_N electrically connected to the ON antifuse cell SAC_N, a relatively large leakage current may be sensed. This may be due to the fact that the antifuse capacitor dielectric layer ADL_N of the ON antifuse capacitor ACAP_N of the ON antifuse cell SAC_N is hard broken down, thereby forming the hard breakdown path HP. Therefore, whether the programmed data is “ON” or “OFF” may be sensed by comparing a difference in the magnitude of the leakage current.

In addition, in the case of the unselected antifuse cell UAC, leakage current may not be sensed regardless of whether the hard breakdown path HP is formed. In some embodiments, when the antifuse capacitor dielectric layer ADL_U of the unselected antifuse capacitor ACAP_U of the unselected antifuse cell UAC includes the hard breakdown path HP, the unselected antifuse cell UAC may be electrically connected to the unselected word line AWL_U, and thus, leakage current may not be sensed. In some other embodiments, if the unselected antifuse cell UAC does not include the hard breakdown path HP, the unselected antifuse cell UAC is electrically connected to the unselected word line AWL_U so that leakage current may not be sensed.

FIG. 14 is a cross-sectional view illustrating a semiconductor memory device 100A according to other embodiments. In detail, FIG. 14 is a diagram illustrating a portion corresponding to the portion “CX2” in FIG. 7.

The semiconductor memory device 100A of FIG. 14 is configured identical or similar to the semiconductor memory device 100 of FIGS. 5 to 10, so the differences are mainly described below.

In one or more embodiments the capacitor dielectric layer DL included in the cell capacitor CAP in the memory cell region MCR and the antifuse capacitor dielectric layer ADL included in the antifuse capacitor ACAP in the antifuse cell region ACR may be formed through separate processes. In some embodiments, the capacitor dielectric layer DL and the antifuse capacitor dielectric layer ADL may comprise different materials. In some embodiments, the thickness t21 of the capacitor dielectric layer DL in the vertical direction (the Z direction) may be different from the thickness t22 of the antifuse capacitor dielectric layer ADL in the vertical direction (the Z direction). For example, the thickness t21 of the capacitor dielectric layer DL in the vertical direction (the Z direction) may be thinner than the thickness t22 of the antifuse capacitor dielectric layer ADL in the vertical direction (the Z direction). In embodiments, the thickness t22 of the antifuse capacitor dielectric layer ADL in the vertical direction (the Z direction) may be thicker than the thickness t21 of the capacitor dielectric layer DL in the vertical direction (the Z direction).

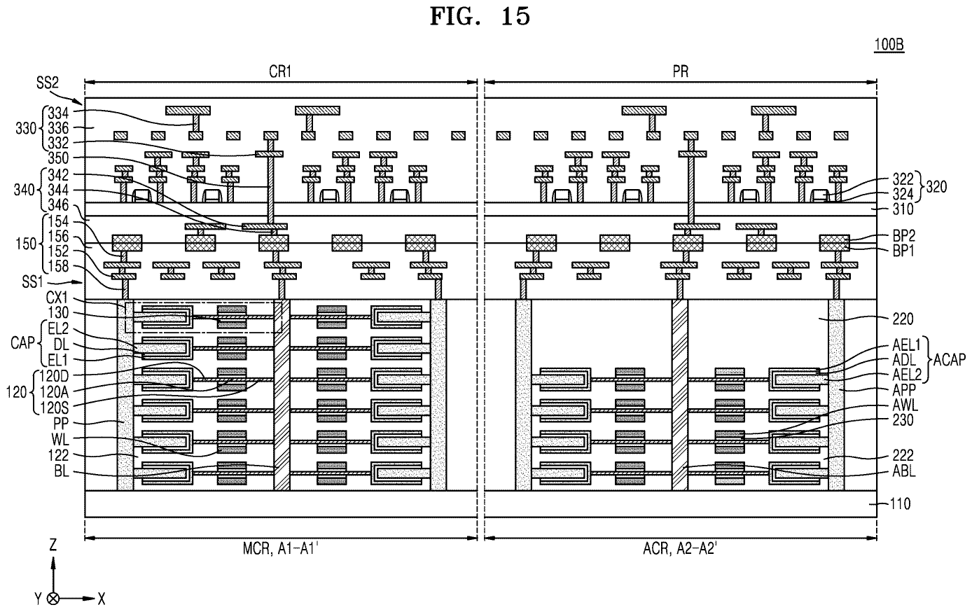

FIG. 15 is a cross-sectional view illustrating a semiconductor memory device 100B according to other embodiments. The semiconductor memory device 100B of FIG. 15 is configured identical or similar to the semiconductor memory device 100 of FIGS. 5 to 10, so the differences are mainly described below.

Referring to FIG. 15, the number of antifuse cells AFC arranged in the vertical direction (the Z direction) or the number of second semiconductor patterns 220 arranged in the vertical direction (the Z direction) in the antifuse cell region ACR may be less than the number of first semiconductor patterns 120 arranged in the vertical direction (the Z direction) in the memory cell region MCR.

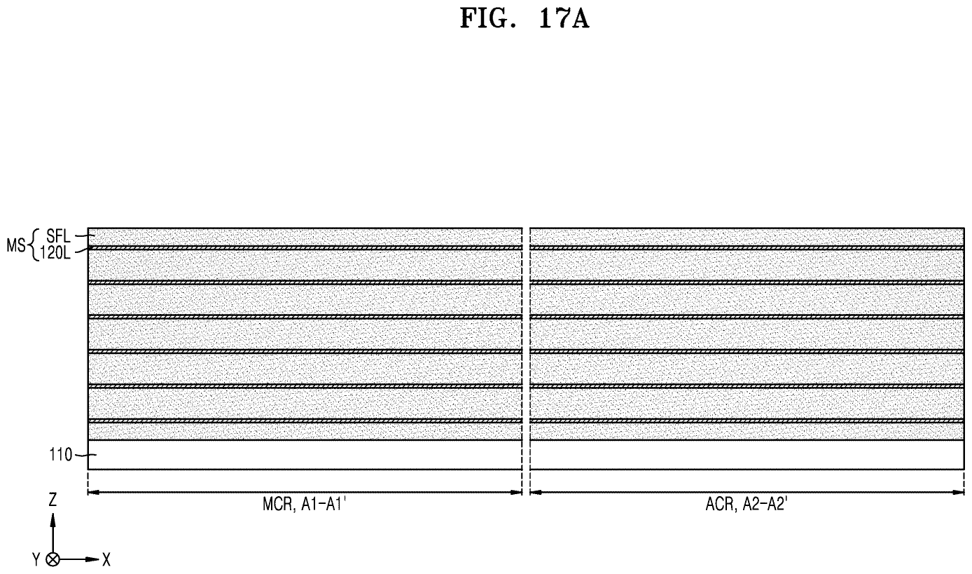

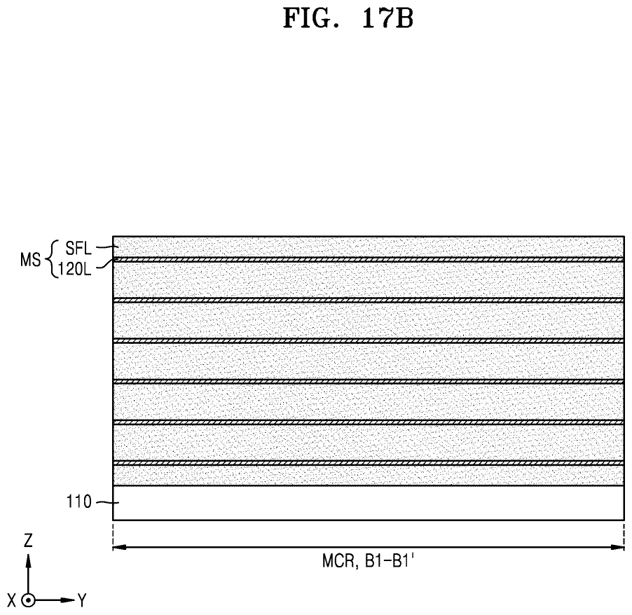

In one or more embodiments the plurality of second semiconductor patterns 220 may be formed simultaneously in a formation process of the plurality of first semiconductor patterns 120. For example, a semiconductor layer 120L (see FIG. 17A) and a sacrificial mold layer SFL (see FIG. 17A) are alternately stacked on the first substrate 110 and then portions of the semiconductor layer 120L are removed, thereby forming the plurality of first semiconductor patterns 120 in the memory cell region MCR and forming the plurality of second semiconductor patterns 220 in the antifuse cell region ACR. Thereafter, among the plurality of second semiconductor patterns 220 in the antifuse cell region ACR, the second semiconductor pattern 220 located on the upper side may be removed and only a portion of the second semiconductor pattern 220 located on the lower side may remain.

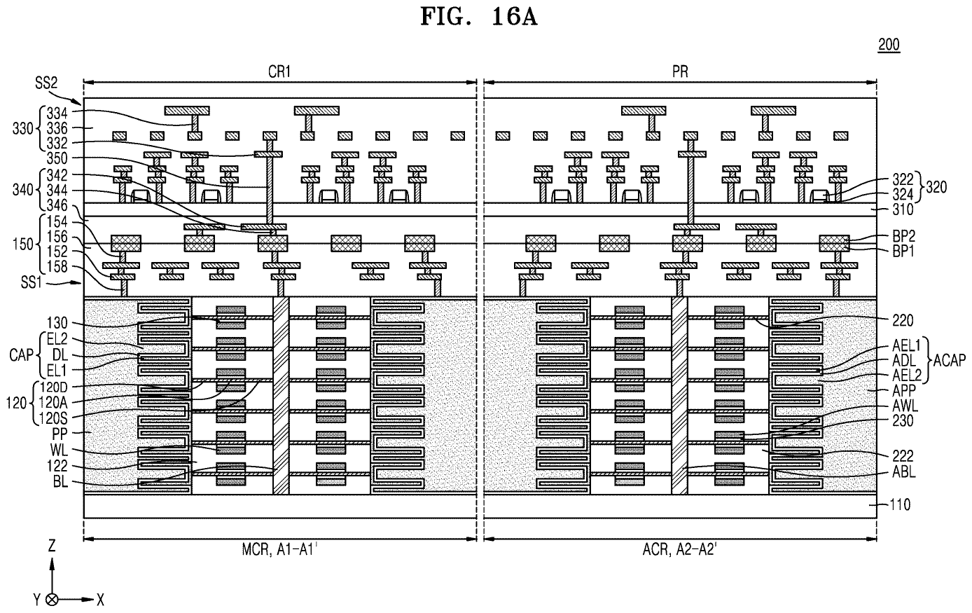

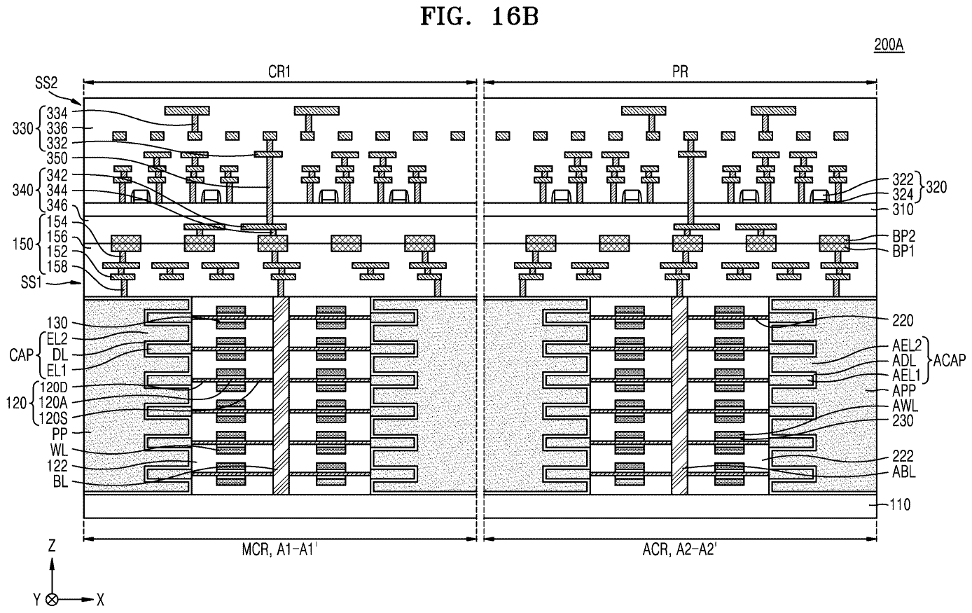

FIGS. 16A and 16B are cross-sectional views illustrating semiconductor memory devices 200 and 200A, respectively, according to different embodiments. The semiconductor memory devices 200 and 200A of FIGS. 16A and 16B are configured identical or similar to the semiconductor memory devices 100 of FIGS. 5 to 10, so the differences are mainly described below.

Referring to FIG. 16A, the cell capacitor CAP may include the first electrode EL1 having a cup shape extending in the first horizontal direction (the X direction), the capacitor dielectric layer DL conformally placed on an internal space and an external surface of the first electrode EL1, and the second electrode EL2 filling the internal space of the first electrode EL1, and the second electrode EL2 and the first plate electrode PP may be formed integrally. The antifuse capacitor ACAP, similar to the cell capacitor CAP, may include the first antifuse electrode AEL1 having a cup shape extending in the first horizontal direction (the X direction), the antifuse capacitor dielectric layer ADL conformally placed on an internal space and an outer surface of the first antifuse electrode AEL1, and the second antifuse electrode AEL2 filling the internal space of the first antifuse electrode AEL1, and the second antifuse electrode AEL2 and the second plate electrode APP may be formed integrally.

Referring to FIG. 16B, the cell capacitor CAP may include the first electrode EL1 having a pillar or bar shape extending in the first horizontal direction (the X direction), the capacitor dielectric layer DL conformally placed on an outer surface of the first electrode EL1, and the second electrode EL2 surrounding the first electrode EL1 on the capacitor dielectric layer DL. In some embodiments, the second electrode EL2 and the first plate electrode PP may be formed integrally. In some other embodiments, the second electrode EL2 may include a thin layer conformally surrounding the capacitor dielectric layer DL, and the first plate electrode PP may cover the second electrode EL2.

The antifuse capacitor ACAP, similar to the cell capacitor CAP, may include the first antifuse electrode AEL1 having a pillar or bar shape extending in the first horizontal direction (the X direction), the antifuse capacitor dielectric layer ADL conformally placed on an outer surface of the first antifuse electrode AEL1, and the second antifuse electrode AEL2 surrounding the first antifuse electrode AEL1 on the antifuse capacitor dielectric layer ADL. In some embodiments, the second antifuse electrode AEL2 may be formed integrally with the second plate electrode APP. In some other embodiments, the second antifuse electrode AEL2 may include a thin layer conformally surrounding the antifuse capacitor dielectric layer ADL, and the second plate electrode APP may cover the second antifuse electrode AEL2.

FIGS. 17A, 17B, 18A, 18B, 19A, 19B, 20A, 20B, 21, 22, 23A and 23B, and 24A and 24B are diagrams sequentially illustrating manufacturing processes of a method of manufacturing a semiconductor memory device, according to embodiments. In detail, FIGS. 17A, 18B, 19A, 20A, 21, 22, 23A, and 24A are diagrams corresponding to cross-sections taken along lines A1-A1′ of FIGS. 5 and A2-A2′ of FIG. 6, and FIGS. 17B, 18B, 19B, 20B, 23B, and 24B are diagrams corresponding to cross-sections taken along lines B1-B1′ of FIG. 5.

Referring to FIGS. 17A and 17B, a sacrificial mold layer SFL and a semiconductor layer 120L may be alternately and sequentially formed on the first substrate 110 to form a mold stack MS. The mold stack MS may be placed in the memory cell region MCR and the antifuse cell region ACR.

In one or more embodiments the sacrificial mold layer SFL and the semiconductor layer 120L may include materials having an etch selectivity with respect to each other. For example, the sacrificial mold layer SFL and the semiconductor layer 120L may each include a single crystal layer of a group IV semiconductor, a group IV-IV compound semiconductor, or a group III-V compound semiconductor, and the sacrificial mold layer SFL and the semiconductor layer 120L may include different materials. In an example, the sacrificial mold layer SFL may include SiGe and the semiconductor layer 120L may include single crystal silicon. The sacrificial mold layer SFL and the semiconductor layer 120L may each have a thickness of several tens of nm, such as 10 nm to 50 nm or 20 to 40 nm.

In one or more embodiments the sacrificial mold layer SFL and the semiconductor layer 120L may be formed by an epitaxy process. For example, the epitaxy process may be vapor-phase epitaxy (VPE), a chemical vapor deposition (CVD) process, such as ultra-high vacuum chemical vapor deposition (UHV-CVD), molecular beam epitaxy, or combinations thereof. In the epitaxy process, a liquid or gaseous precursor may be used as a precursor for forming the sacrificial mold layer SFL and the semiconductor layer 120L.

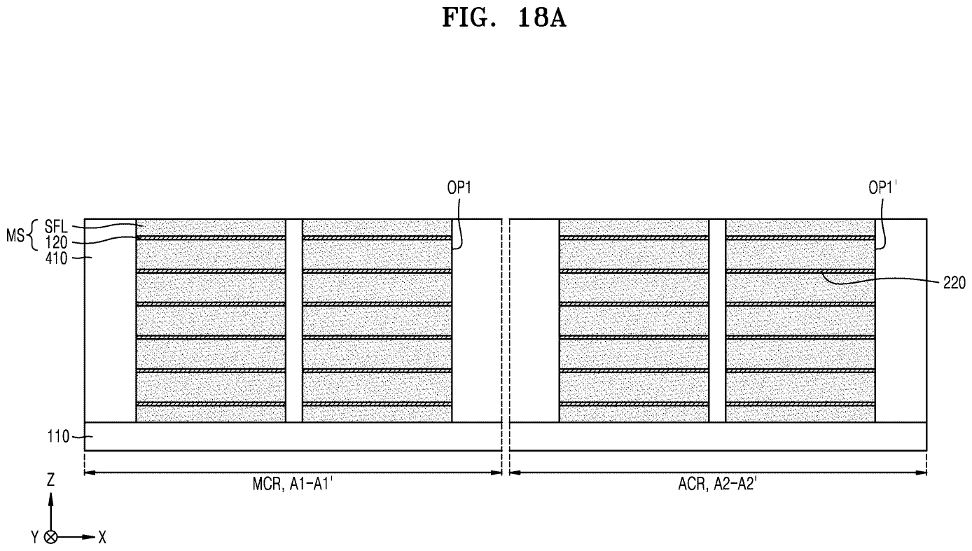

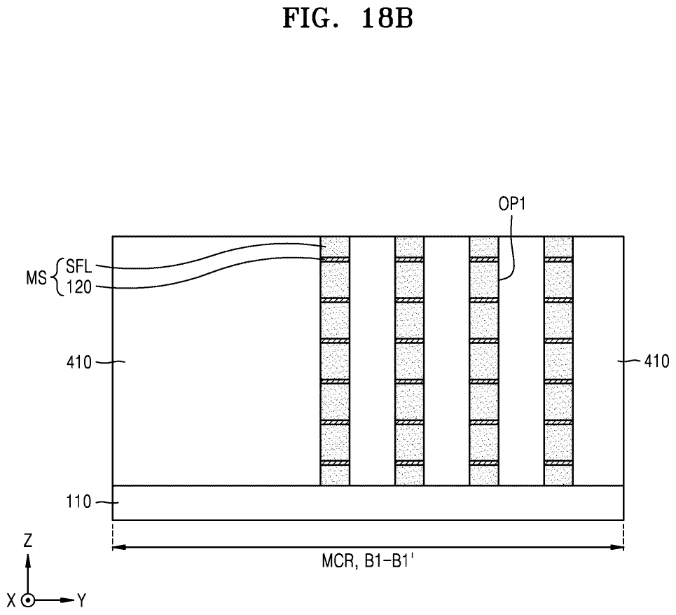

Referring to FIGS. 18A and 18B, a mask pattern (not shown) may be formed on the mold stack MS, and a portion of the mold stack MS may be removed using the mask pattern as an etching mask to form a first opening OP1 and a first antifuse opening OP1′. Thereafter, a first insulating layer 410 may be formed within the first opening OP1 and the first antifuse opening OP1′.

In one or more embodiments the plurality of first semiconductor patterns 120 may be formed from the semiconductor layer 120L within the memory cell region MCR by forming the first opening OP1, and the plurality of second semiconductor patterns 220 may be formed from the semiconductor layer 120L within the antifuse cell region ACR by forming the first antifuse opening OP1′. In examples, the plurality of first semiconductor patterns 120 may be formed by patterning portions of the semiconductor layer 120L disposed in the memory cell region MCR, and the plurality of second semiconductor patterns 220 may be formed by patterning portions of the semiconductor layer 120L disposed in the antifuse cell region ACR.

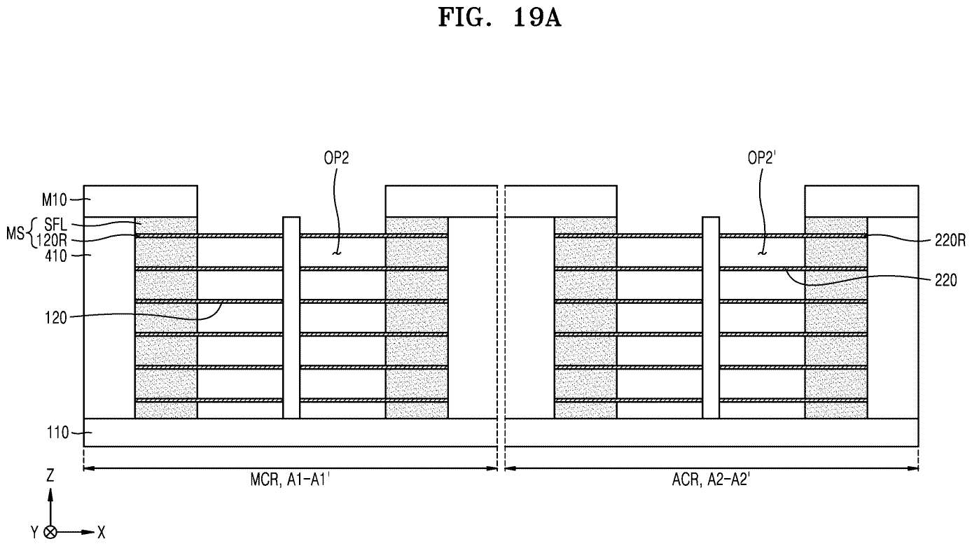

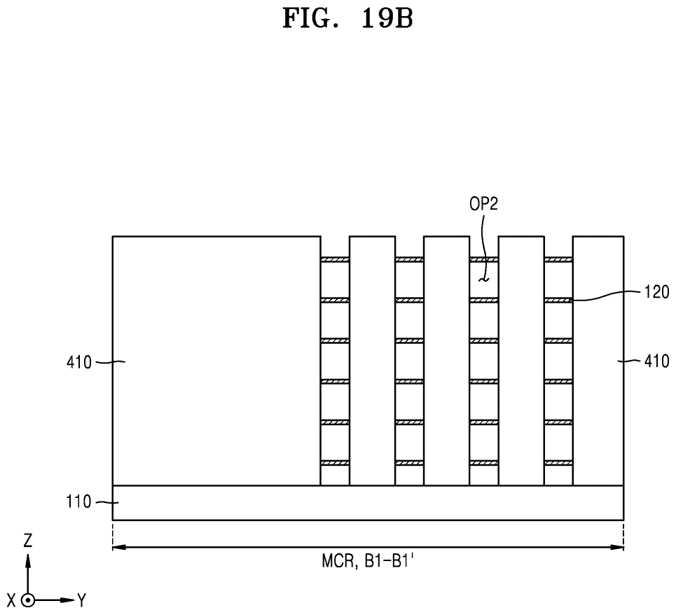

Referring to FIGS. 19A and 19B, the sacrificial mold layer SFL may be removed to form the second opening OP2 between the plurality of first semiconductor patterns 120, and the second antifuse opening OP2′ may be formed between the plurality of second semiconductor patterns 220.

In some embodiments, as illustrated in FIG. 19A, a mask pattern M10 may be formed on the mold stack MS of the memory cell region MCR and the antifuse cell region ACR, a portion of the sacrificial mold layer SFL not covered by the mask pattern M10 may be removed, and portions of the sacrificial mold layer SFL positioned to vertically overlap with the mask pattern M10 may not be removed but remain. In examples, portions of the first semiconductor pattern 120 and the second semiconductor pattern 220 covered by the sacrificial mold layer SFL are referred to as residual patterns 120R and 220R, respectively. The mask pattern M10 may be placed on a structure in which the residual patterns 120R and 220R and sacrificial mold layers SFL are alternately stacked.

In one or more embodiments the removal process of the sacrificial mold layer SFL may be a wet etching process or a pullback process. For example, the removal process of the sacrificial mold layer SFL may be an etching process using an etch selectivity between the sacrificial mold layer SFL and the semiconductor layer 120L. For example, during a wet etching process or a pullback process, an etching rate of the plurality of first semiconductor patterns 120 and the plurality of second semiconductor patterns 220 may be relatively low, and an etching rate of the sacrificial mold layer SFL may be relatively high.

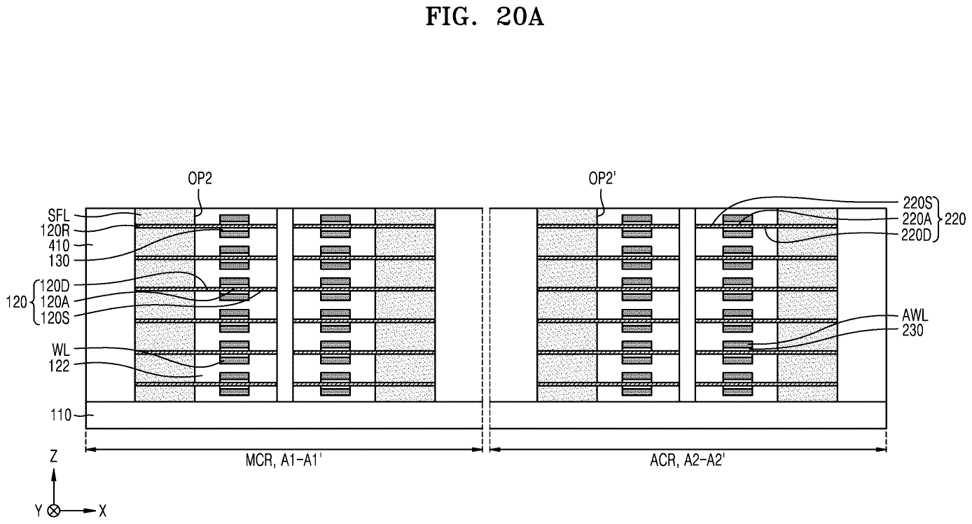

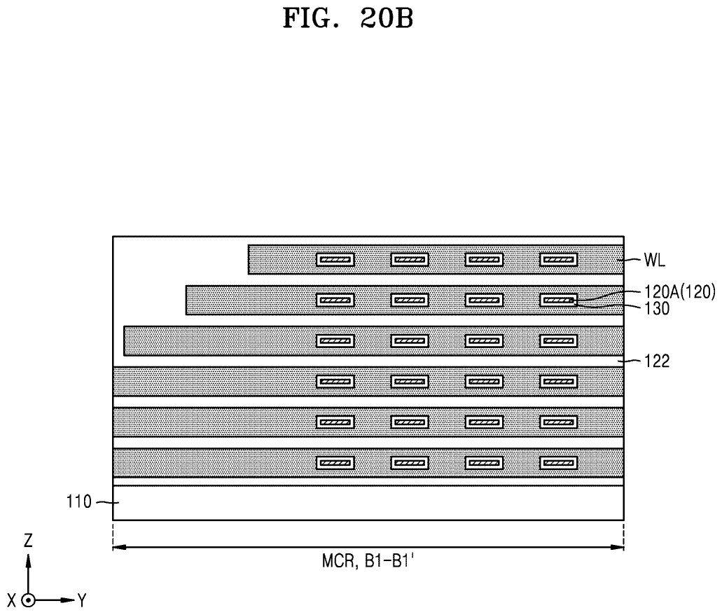

Referring to FIGS. 20A and 20B, the first gate insulating layer 130 and the first word line WL may be sequentially formed on the upper, side, and bottom surfaces of the plurality of first semiconductor patterns 120 within the second opening OP2 in the memory cell region MCR. For example, the first gate insulating layer 130 may be conformally arranged to surround the plurality of first semiconductor patterns 120, and the first word line WL may be arranged to surround the plurality of first semiconductor patterns 120 on the first gate insulating layer 130 and extend in the second horizontal direction (the Y direction).

In addition, the second gate insulating layer 230 and the second word line AWL may be sequentially formed on the upper, side, and bottom surfaces of each second semiconductor pattern of the plurality of second semiconductor patterns 220 within the second antifuse opening OP2′ in the antifuse cell region ACR. For example, the second gate insulating layer 230 may be conformally arranged to surround the plurality of second semiconductor patterns 220, and the second word line AWL may be arranged to surround the plurality of second semiconductor patterns 220 on the second gate insulating layer 230 and extend in the second horizontal direction (the Y direction).

In one or more embodiments as illustrated in FIG. 20A, portions of the first gate insulating layer 130 and the first word line WL arranged at opposite end portions (e.g., opposite end portions in the first horizontal direction (the X direction)) of the plurality of first semiconductor patterns 120 within the second opening OP2 may be removed. In addition, portions of the second gate insulating layer 230 and the second word line AWL arranged at opposite end portions of the plurality of second semiconductor patterns 220 within the second antifuse opening OP2′ may be removed.

Thereafter, the first mold insulating layer 122 filling the inside of the second opening OP2 and the second mold insulating layer 222 filling the second antifuse opening OP2′ may be formed. In some embodiments, the first mold insulating layer 122 may be located between two first word lines WL adjacent in the vertical direction (the Z direction) and between end portions of two first semiconductor patterns 120 adjacent in the vertical direction (the Z direction). The second mold insulating layer 222 may be located between two second word lines AWL adjacent in the vertical direction (the Z direction) and between the end portions of two second semiconductor patterns 220 adjacent in the vertical direction (the Z direction).

In one or more embodiments a portion of the first word line WL may be removed to form the word line pad WLP. The word line pad WLP may be placed in a step shape, and for example, the word line pad WLP connected to one first word line WL may be apart from the word line pad WLP connected to another first word line WL placed below the one first word line WL in the second horizontal direction (the Y direction).

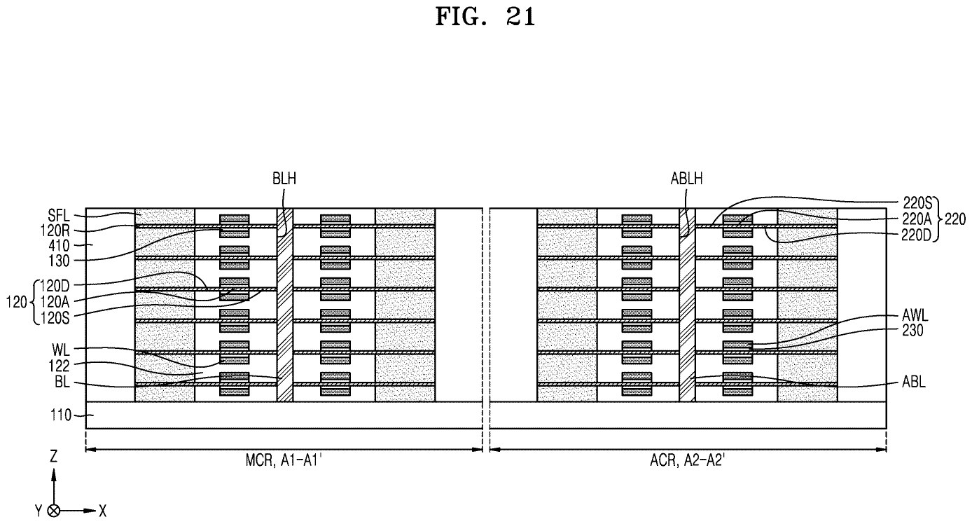

Referring to FIG. 21, in the memory cell region MCR, a portion of the insulating layer 410 may be removed to form a first bit line opening BLH, and the first bit line BL may be formed within the first bit line opening BLH. In addition, in the antifuse cell region ACR, a portion of the insulating layer 410 may be removed to form a second bit line opening ABLH, and the second bit line ABL may be formed within the second bit line opening ABLH.

In one or more embodiments as illustrated in FIG. 21, two first semiconductor patterns 120 may be arranged apart from each other in the first horizontal direction (the X direction) with the first bit line BL therebetween, and one sidewall of one first bit line BL may be in contact with a first impurity region 120S of one first semiconductor pattern 120, and the other sidewall of one first bit line BL opposite to the one sidewall may be in contact with the first impurity region 120S of another first semiconductor pattern 120. In addition, two second semiconductor patterns 220 may be arranged apart from each other in the first horizontal direction (the X direction) with the second bit line ABL therebetween, and one sidewall of one second bit line ABL may be in contact with the first antifuse impurity region 220S of one second semiconductor pattern 220 and the other sidewall of the one second bit line ABL opposite to the one sidewall may be in contact with the first antifuse impurity region 220S of the other second semiconductor pattern 220.

In embodiments, two first semiconductor patterns 120 arranged at the same vertical level may be electrically connected to one first bit line BL, and two second semiconductor patterns 220 arranged at the same vertical level may be electrically connected to one second bit line ABL, but the technical idea of the disclosures is not limited thereto.

In one or more embodiments the manufacturing processes described above with reference to FIGS. 17A, 17B to 21 may be performed simultaneously during the same process in the memory cell region MCR and the antifuse cell region ACR. However, the technical idea of the disclosures is not limited to manufacturing a resultant structure of FIG. 21 by the same process simultaneously in the memory cell region MCR and the antifuse cell region ACR, and, if necessary, a different process separate from the process performed in the memory cell region MCR may be performed in the antifuse cell region ACR.

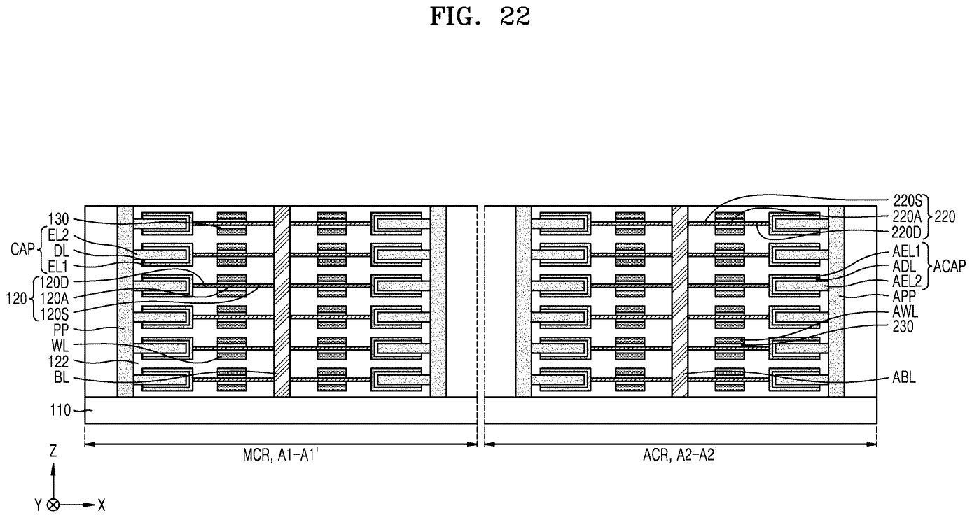

Referring to FIG. 22, the sacrificial mold layer SFL and the residual pattern 120R may be removed from the memory cell region MCR, and the cell capacitor CAP may be formed at a location in which the sacrificial mold layer SFL and the residual pattern 120R were removed.

In one or more embodiments the cell capacitor CAP may include the first electrode EL1, the capacitor dielectric layer DL, and the second electrode EL2. The first electrode EL1 may be electrically connected to the second impurity region 120D of the first semiconductor pattern 120 and may have an internal space extending in the first horizontal direction (the X direction). The capacitor dielectric layer DL may be conformally arranged within the internal space, and the internal space may be filled with the second electrode EL2.

In addition, the sacrificial mold layer SFL and the residual pattern 220R may be removed from the antifuse cell region ACR, and the antifuse capacitor ACAP may be formed at a location in which the sacrificial mold layer SFL and the residual pattern 220R were removed.

In one or more embodiments the antifuse capacitor ACAP may include the first antifuse electrode AEL1, the antifuse capacitor dielectric layer ADL, and the second antifuse electrode AEL2. The first antifuse electrode AEL1 may be electrically connected to the second antifuse impurity region 220D of the second semiconductor pattern 220 and may have an internal space extending in the first horizontal direction (the X direction). The antifuse capacitor dielectric layer ADL may be conformally arranged within the internal space, and the internal space may be filled with the second antifuse electrode AEL2.

In one or more embodiments the cell capacitor CAP and the antifuse capacitor ACAP may be formed simultaneously through the same process. In some embodiments, a vertical thickness of the capacitor dielectric layer DL of the cell capacitor CAP may be equal to a vertical thickness of the antifuse capacitor dielectric layer ADL of the antifuse capacitor ACAP. In some embodiments, the capacitor dielectric layer DL and the antifuse capacitor dielectric layer ADL of the cell capacitor CAP may be the same material. In other embodiments, the cell capacitor CAP and the antifuse capacitor ACAP may be formed through separate different processes. In some embodiments, a vertical thickness of the capacitor dielectric layer DL of the cell capacitor CAP may be different from a vertical thickness of the antifuse capacitor dielectric layer ADL of the antifuse capacitor ACAP. For example, the vertical thickness of the antifuse capacitor dielectric layer ADL of the antifuse capacitor ACAP may be greater than the vertical thickness of the capacitor dielectric layer DL of the cell capacitor CAP. In some embodiments, the capacitor dielectric layer DL and the antifuse capacitor dielectric layer ADL of the cell capacitor CAP may be different materials.

As described above, when some of the memory cells in the memory cell region MCR are defective, the antifuse capacitor ACAP in the antifuse cell region ACR has to form a hard breakdown path that electrically connects the first antifuse electrode AEL1 to the second antifuse electrode AEL2 by breaking down the antifuse capacitor dielectric layer ADL for a programming operation of the antifuse cell AFC, and therefore, the antifuse capacitor dielectric layer ADL may be configured to have a different thickness and/or be a different material than the capacitor dielectric layer DL included in the cell capacitor CAP in the memory cell region MCR depending on a breakdown voltage to be set.

Thereafter, the first plate electrode PP electrically connected to the second electrode EL2 of the cell capacitor CAP and extending in the second horizontal direction (the Y direction) and the second plate electrode APP electrically connected to the second antifuse electrode AEL2 of the antifuse capacitor ACAP and extending in the second horizontal direction (the Y direction) may be formed.

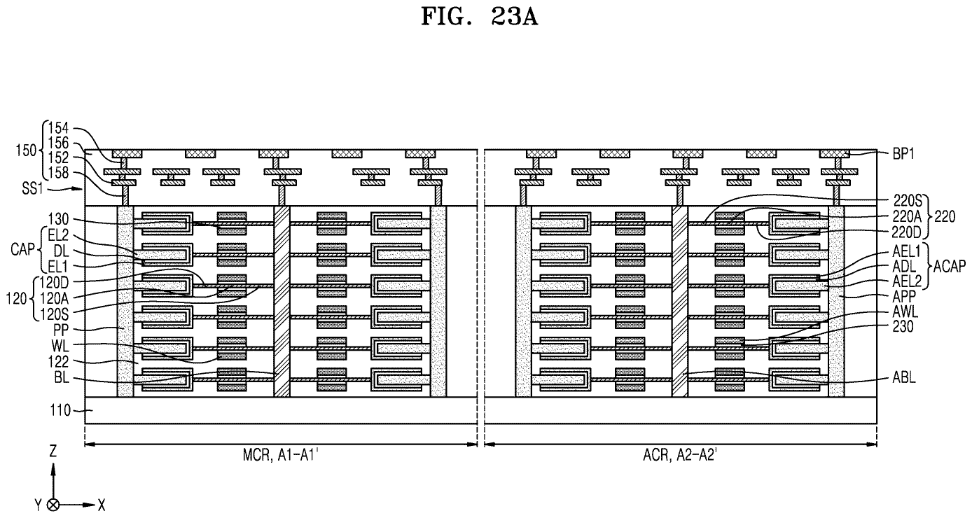

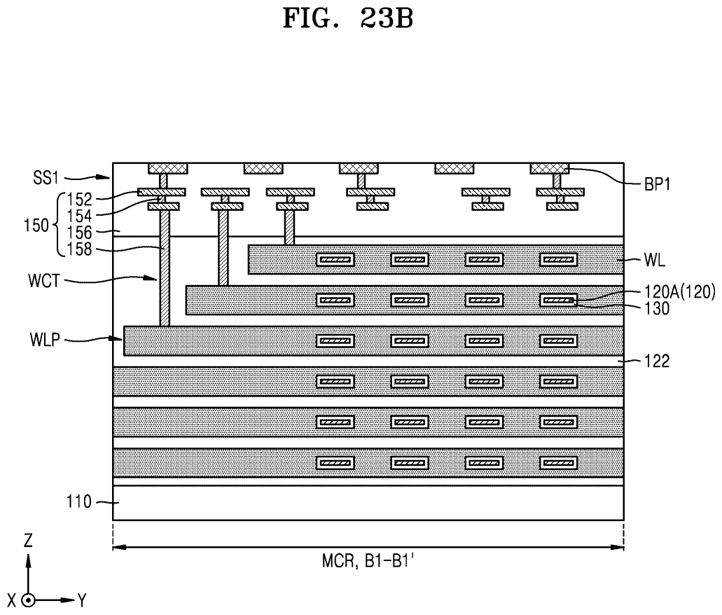

Referring to FIGS. 23A and 23B, the upper interconnection structure 150 may be formed in the memory cell region MCR and the antifuse cell region ACR. The upper interconnection structure 150 may include the interconnection layer 152, the via 154, the insulating layer 156, and the contact 158. For example, the contact 158 may be electrically connected to the first bit line BL, the first word line WL, and the first plate electrode PP. Thereafter, the first bonding pad BP1 may be formed on the upper interconnection structure 150 and placed in the same plane as a top surface of the insulating layer 156.

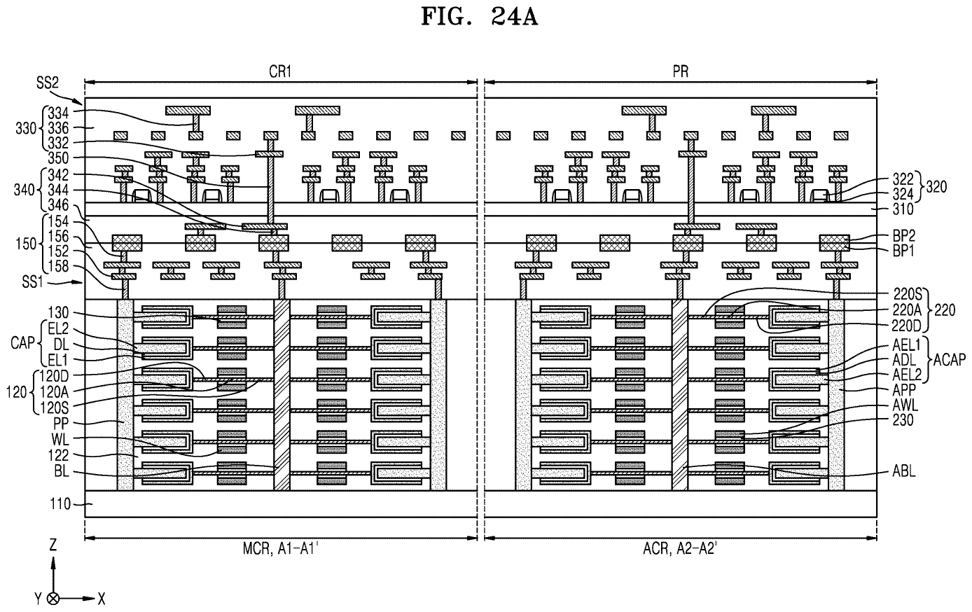

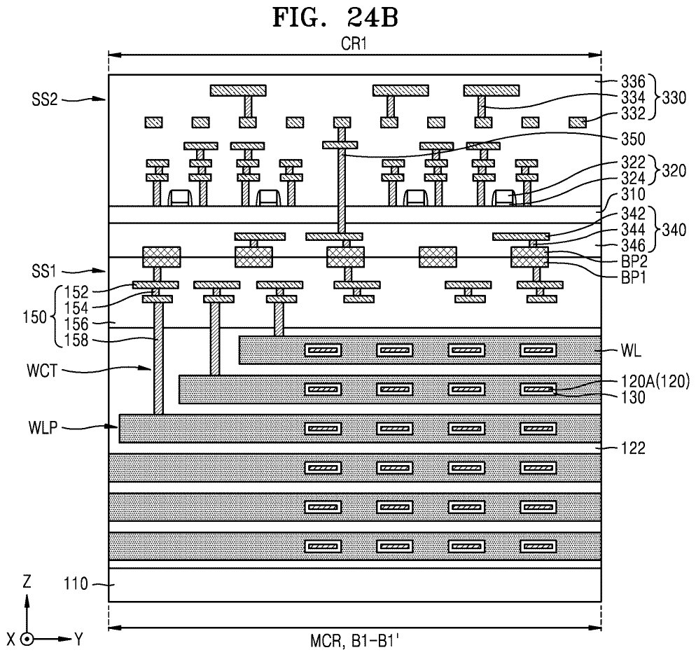

Referring to FIGS. 24A and 24B, the second stack structure SS2 may be prepared.

In one or more embodiments the second stack structure SS2 may include the second substrate 310, the peripheral circuit transistor 320 placed on the second substrate 310, the front interconnection structure 330 covering the peripheral circuit transistor 320 on an upper surface of the second substrate 310, and the rear interconnection structure 340 disposed on the bottom surface of the second substrate 310.

In one or more embodiments the peripheral circuit transistor 320 may be formed on a first surface (or upper surface) of the second substrate 310, the front interconnection structure 330 may be formed on the first surface of the second substrate 310, a carrier substrate may be attached on the front interconnection structure 330, and then, a second surface (or bottom surface) of the second substrate 310 may be ground to thin the second substrate 310. Thereafter, the rear interconnection structure 340 and the second bonding pad BP2 may be formed on the second surface of the second substrate 310, thereby completing the second stack structure SS2.

Thereafter, the second stack structure SS2 may be bonded to the first stack structure SS1, and the first bonding pad BP1 of the first stack structure SS1 may be bonded to the second bonding pad BP2 of the second stack structure SS2. The upper surface of the insulating layer 156 may be bonded to the bottom surface of the insulating layer 346.

While the disclosure has been particularly shown and described with reference to embodiments thereof, it will be understood that the invention is not limited thereto, and various changes in form and details may be made therein without departing from the spirit and scope of the following claims.

What is claimed is:

1. A semiconductor memory device comprising:
a first stack structure including:
a first substrate,
a memory cell region including a plurality of memory cells and a plurality of cell capacitors arranged three-dimensionally on the first substrate, and
an antifuse cell region including a plurality of antifuse cells and a plurality of antifuse capacitors arranged three-dimensionally on the first substrate; and
a second stack structure disposed on the first stack structure and including:
a second substrate,
a core region positioned to vertically overlap the memory cell region on the second substrate and electrically connected to the memory cell region, and
a peripheral circuit region positioned to vertically overlap the antifuse cell region on the second substrate.

2. The semiconductor memory device of claim 1, wherein
the memory cell region of the first stack structure includes
a first semiconductor pattern extending on the first substrate in a first horizontal direction parallel to an upper surface of the first substrate,
a word line surrounding the first semiconductor pattern and extending in a second horizontal direction intersecting the first horizontal direction, and
a first bit line connected to a first end portion of the first semiconductor pattern and extending in a vertical direction.

3. The semiconductor memory device of claim 2, wherein each cell capacitor of the plurality of cell capacitors is connected to a second end portion of the first semiconductor pattern opposite to the first end portion of the first semiconductor pattern and extends in the first horizontal direction.

4. The semiconductor memory device of claim 2, wherein
the antifuse cell region of the first stack structure includes,
a second semiconductor pattern extending in the first horizontal direction parallel to the upper surface of the first substrate on the first substrate,
a second word line surrounding the second semiconductor pattern and extending in the second horizontal direction intersecting the first horizontal direction, and
a second bit line connected to a first end portion of the second semiconductor pattern and extending in the vertical direction.

5. The semiconductor memory device of claim 4, wherein
an antifuse capacitor of the plurality of antifuse capacitors is connected to a second end portion of the second semiconductor pattern opposite to the first end portion of the second semiconductor pattern, and extends in the first horizontal direction.

6. The semiconductor memory device of claim 1, wherein
a cell capacitor of the plurality of cell capacitors includes a first electrode and a second electrode and a capacitor dielectric layer between the first electrode and the second electrode, and
an antifuse capacitor of the plurality of antifuse capacitors includes a first antifuse electrode, a second antifuse electrode and an antifuse capacitor dielectric layer between the first antifuse electrode and the second antifuse electrode.

7. The semiconductor memory device of claim 6, wherein the capacitor dielectric layer and the antifuse capacitor dielectric layer have different thicknesses.

8. The semiconductor memory device of claim 6, wherein the capacitor dielectric layer and the antifuse capacitor dielectric layer are different materials.

9. The semiconductor memory device of claim 6, wherein the antifuse capacitor dielectric layer is broken down to have a hard breakdown path that electrically connects the first antifuse electrode to the second antifuse electrode.

10. The semiconductor memory device of claim 1, wherein each of the plurality of antifuse cells is arranged at the same vertical level as a corresponding memory cell of the plurality of memory cells.

11. The semiconductor memory device of claim 1, wherein a number of antifuse cells of the plurality of antifuse cells arranged in a vertical direction is the same as a number of memory cells of the plurality of memory cells arranged in the vertical direction.

12. A semiconductor memory device comprising:
a first stack structure including:
a first substrate,
a memory cell region including a plurality of memory cells and a plurality of cell capacitors arranged three-dimensionally on the first substrate, and
an antifuse cell region including a plurality of antifuse cells and a plurality of antifuse capacitors arranged three-dimensionally on the first substrate; and
a second stack structure disposed on the first stack structure and including:
a second substrate,
a core region positioned to vertically overlap the memory cell region on the second substrate and electrically connected to the memory cell region, and
a peripheral circuit region positioned to vertically overlap the antifuse cell region on the second substrate,
wherein each of the plurality of antifuse cells includes:
a second semiconductor pattern extending in a first horizontal direction parallel to an upper surface of the first substrate in the antifuse cell region, the second semiconductor pattern including a first antifuse impurity region and a second antifuse impurity region arranged in the first horizontal direction with an antifuse channel region therebetween;
a second word line surrounding the antifuse channel region of the second semiconductor pattern and extending in a second horizontal direction intersecting the first horizontal direction; and
a second bit line contacting the first antifuse impurity region of the second semiconductor pattern and extending in a vertical direction,
wherein an antifuse capacitor of the plurality of antifuse capacitors is in contact with the second antifuse impurity region of the second semiconductor pattern.

13. The semiconductor memory device of claim 12, wherein
each of the plurality of memory cells of the first stack structure includes:
a first semiconductor pattern extending in the first horizontal direction in the memory cell region, the first semiconductor pattern including a channel region and a first impurity region and a second impurity region arranged in the first horizontal direction with the channel region therebetween;
a word line surrounding the channel region of the first semiconductor pattern and extending in the second horizontal direction; and
a first bit line contacting the first impurity region of the first semiconductor pattern and extending in the vertical direction.

14. The semiconductor memory device of claim 12, wherein
each cell capacitor of the plurality of cell capacitors includes a first electrode and a second electrode and a capacitor dielectric layer between the first electrode and the second electrode, and
each antifuse capacitor of the plurality of antifuse capacitors includes a first antifuse electrode and a second antifuse electrode and an antifuse capacitor dielectric layer between the first antifuse electrode and the second antifuse electrode.

15. The semiconductor memory device of claim 14, wherein the capacitor dielectric layer and the antifuse capacitor dielectric layer have different thicknesses.

16. The semiconductor memory device of claim 14, wherein the capacitor dielectric layer and the antifuse capacitor dielectric layer are different materials.

17. The semiconductor memory device of claim 12, wherein each of the plurality of cell capacitors is arranged at the same vertical level as each of the plurality of antifuse capacitors.

18. The semiconductor memory device of claim 12, wherein a number of cell capacitors of the plurality of cell capacitors in the vertical direction is the same as a number of antifuse capacitors of the plurality of antifuse capacitors in the vertical direction.

19. A semiconductor memory device comprising:
a first stack structure including
a first substrate,
a memory cell region including a plurality of memory cells and a plurality of cell capacitors arranged three-dimensionally on the first substrate, and
an antifuse cell region including a plurality of antifuse cells and a plurality of antifuse capacitors arranged three-dimensionally on the first substrate; and
a second stack structure disposed on the first stack structure and including
a second substrate,
a core region positioned to vertically overlap the memory cell region on the second substrate and electrically connected to the memory cell region, and
a peripheral circuit region positioned to vertically overlap the antifuse cell region on the second substrate,
wherein each of the plurality of memory cells of the first stack structure includes:
a first semiconductor pattern on the first substrate in the memory cell region and extending in a first horizontal direction parallel to an upper surface of the first substrate;
a word line surrounding the first semiconductor pattern and extending in a second horizontal direction parallel to an upper surface of the first substrate; and
a first bit line connected to a first end portion of the first semiconductor pattern and extending in a vertical direction,
wherein each of the plurality of antifuse cells of the first stack structure includes:
a second semiconductor pattern on the first substrate in the antifuse cell region and extending in the first horizontal direction;
a word line surrounding the second semiconductor pattern and extending in the second horizontal direction; and
a second bit line connected to a first end portion of the second semiconductor pattern and extending in the vertical direction, and
wherein the first semiconductor pattern, the second semiconductor pattern, each of the plurality of cell capacitors, and each of the plurality of antifuse capacitors are arranged at the same vertical level.

20. The semiconductor memory device of claim 19, wherein
each cell capacitor of the plurality of cell capacitors is connected to a second end portion of the first semiconductor pattern opposite to the first end portion of the first semiconductor pattern and extending in the first horizontal direction, and
each antifuse capacitor of the plurality of antifuse capacitors is connected to a second end portion of the second semiconductor pattern opposite to the first end portion of the second semiconductor pattern and extending in the first horizontal direction.
